(19) United States
(12) Patent Application Publication
(10) Pub. No.: US 2008/0214008 A1
(43) Pub. Date: Sep. 4, 2008

(54) METHOD OF MANUFACTURING SEMICONDUCTOR DEVICE

(75) Inventors: Masashige Moritoki, Kanagawa (JP); Masato Fujita, Kanagawa (JP)

Correspondence Address: YOUNG & THOMPSON, 209 Madison Street, Suite 500, ALEXANDRIA, VA, 22314, US

(73) Assignee: NEC ELECTRONICS CORPORATION, KANAGAWA (JP)

(21) Appl. No.: 11/964,074

(22) Filed: Dec. 26, 2007

(30) Foreign Application Priority Data
Dec. 22, 2006 (JP) 2006346642

(51) Int. Cl. H01L 21/311

(52) U.S. Cl. 438/694; 257/E21.249

(57) ABSTRACT

In a method of manufacturing a semiconductor device, a plurality of structures are formed on a substrate, and a coating film is formed over a whole surface of the substrate to cover the plurality of structures. A photoresist layer is formed to have an opening portion above a target structure of the plurality of structures, and the coating film on a side of the opening is etched to expose a part of the target structure by using the photoresist layer as a mask while maintaining the substrate in a state covered with the coating film. Also, a target portion as at least a portion of the target structure is etched while leaving the coating film, and the photoresist layer and the coating film are removed.

### BACKGROUND OF THE INVENTION

1. Field of the Invention

The present invention relates to a method of manufacturing a semiconductor device, and more specifically, to a technique of etching structures formed on a semiconductor substrate. This application is based on Japanese Patent Application No. 2006-346642. The disclosure of the application is incorporated herein by reference.

2. Description of Related Art

In a manufacturing process of a semiconductor device, there is a case that etching is performed selectively only to a part of a plurality of structures formed over the semiconductor substrate. An exemplary case is a case of forming gate electrodes. In such a case, a plurality of gate electrodes are formed at constant interval, and subsequently a part of the gate electrodes is etched away or a part of each electrode is removed. A process in which the gate electrodes are formed at constant interval once is effective in order to improve processing precision of the gate electrodes.

Another example is a case that the FUSI (Full Silicide) structure is adopted for the gate electrode, as disclosed in Japanese Laid Open Patent Applications (JP-P2006-100431A and JP-P2006-140320A). When the FUSI structure is adopted, silicidization of the gate electrodes is performed in different processes for NMOS transistors and for PMOS transistors. Etching is performed to expose gate electrodes of the NMOS transistors while an area for the PMOS transistors is covered with a photoresist layer, and then (after removing the photoresist layer) the gate electrodes of the NMOS transistors are silicided. Similarly, etching is performed to expose the gate electrodes of the PMOS transistors while covering the area for the NMOS transistors with a photoresist layer, and then (after removing the photoresist layer) the gate electrodes of the PMOS transistors are silicided.

In one method of etching only a part of a plurality of structures formed over a semiconductor substrate, a photoresist layer is formed in such a manner that only the structures to be etched are exposed in an opening and subsequently the exposed portions are removed by etching (for example, see Japanese Laid Open Patent Applications (JP-P-2005-51249A, JP-P2002-319573A, and JP-P2002-359352A).

When such a method is adopted, there is a case that it becomes important to protect a base (base structure) for supporting the structures to be etched. If an alignment error is considered in the photolithography process, the opening of the photoresist layer must be formed to be wider than the structure to be etched, and the base will also be exposed partially within the opening of the photoresist layer. The base structure may be damaged when the etching is performed under the state of the base structure being exposed. For example, when a plurality of gate electrodes is etched, if the semiconductor substrate happens to be partially exposed, the semiconductor substrate will be likely to be damaged.

More specifically, Japanese Laid Open Patent Application (JP-P2002-184860A) discloses a technique of protecting the semiconductor substrate using a coating film when a SiN protective film formed on the gate electrode is removed. FIGS. 1A to 1D are sectional views showing a method of manufacturing a semiconductor device disclosed in the Japanese Laid Open Patent Application (JP-P2002-184860A).

First, as shown in FIG. 1A, gate electrodes 111 are formed over a semiconductor substrate 110. Each of the gate electrodes 111 is formed of a polysilicon film 112, a WSi film 113, and a protection film 114. The protection film 114 is formed of silicon nitride (SiN).

Subsequently, as shown in FIG. 1B, a coating film 401 of organic material is formed by spin coating. An anti-reflective film may be used as the coating film 401. The coating film 401 is formed to cover a partial area of the semiconductor substrate 110 where the gate electrode 111 is not formed. It should be noted that the coating film 401 is not formed on a top surface of the gate electrode 111.

Subsequently, as shown in FIG. 1C, a photoresist layer 402 is formed to selectively expose the gate electrodes 111 whose protective films 114 are to be removed. Subsequently, the etching is performed under the condition that the etching rates of the coating film 401 and the photoresist layer 402 are considerably low as compared with the etching rate of the silicon nitride.

Further, as shown in FIG. 1D, the coating film 401 and the photoresist layer 402 are removed by ashing. Through such a process, the protection film 114 of the gate electrodes 111 can selectively be removed and the desired structure of gate electrodes can be obtained.

However, the present inventor has discovered that technique disclosed in Japanese Laid Open Patent Application (JP-P2002-184860A) cannot suppress etching un-uniformity caused by varieties of the pattern (packing) density and the pattern size on a substrate. As shown in FIG. 2A, when the coating film 401 is formed by spin coating, the top surface of the gate electrode 111 is covered with the coating film 401 in an area where the packing density of the gate electrode 111 is high (an area A of FIG. 2A) and in an area where the gate electrodes 111 is large (an area B of FIG. 2A). If there exist the protection film 114 on whose top surface the coating film 401 is formed and the protection film 114 on whose top surface the coating film 401 is not formed, etching of the protection film 114 becomes difficult. For example, it is supposed that the protection films 114 of the gate electrodes 111 located in areas A to C in FIG. 2A are removed. A top surface of the gate electrodes 111 is covered with the coating film 401 in the area A because of the high density of the gate electrodes 111, and the top surface of the gate electrode 111 is covered with the coating film 401 in the area B because of the large area of the gate electrodes 111. On the other hand, in the area C, the coating film 401 does not cover the top surfaces of the gate electrodes 111. Moreover, in order to remove the protection film 114 of the gate electrode 111 located in the area A to the area C, an opening is provided in the photoresist 402 in the area A to the area C.

In such a case, when the etching is performed under condition that the etching selectivity of the protection film 114 to the coating film 401 is high (namely, under the condition that an etching rate of the protection film 114 is high, and the etching rate of the coating film 401 is low) as shown in FIG. 2B, the protection films 114 of the gate electrodes 111 in either the area A and the area B are not removed because they are covered with the coating film 401 while the protection film 114 of the gate electrode 111 can be removed in the area C.

On the other hand, when the etching is performed under the condition that the etching selectivity of the protection film 114 to the coating film 401 is low, the coating film 401 is etched in the area C and the semiconductor substrate 110 is exposed as shown in FIG. 2C. It is likely that the semiconductor substrate 110 is damaged. Especially, when a difference ΔH1 of the height of the top surface of the coating film 401 between the area A (or B) and the area C is large, it is difficult to surely etch the protection films 114 of the gate electrodes 111 located in the areas A (and B) without damaging the semiconductor substrate 110 in the area C.

The Japanese Laid Open Patent Application (JP-P2002-184860A) discloses that in a location where the adjacent gate electrodes 111 are arranged with a high packing density and in a location where the width of the gate electrode 111 is wide, it is likely that the coating film 401 is formed on the protection film 114. As a measure against this problem, an etching selectivity is controlled as a solution. However, it is actually difficult to selectively remove the protection film 114 from the target gate electrode 111 by controlling the etching selectivity.

### SUMMARY

In an first aspect of the present invention, a method of manufacturing a semiconductor device, includes: forming a plurality of structures on a semiconductor substrate; forming a coating film over a whole surface of the semiconductor substrate to cover the plurality of structures; forming a photoresist layer to have an opening portion above a target structure of the plurality of structures; etching the coating film on a side of the opening to expose a part of the target structure by using the photoresist layer as a mask while maintaining the semiconductor substrate in a state covered with the coating film; etching a target portion to remove at least a portion of the target structure while leaving the coating film; and removing the photoresist layer and the coating film.

According to the present invention, even if there are varieties of a packing density and a size of the structure, it is possible to selectively etch a target structure while protecting a base (base structure) for supporting the target structure to be etched.

### BRIEF DESCRIPTION OF THE DRAWINGS

The above and other objects, advantages and features of the present invention will be more apparent from the following description of certain embodiments taken in conjunction with the accompanying drawings, in which:

FIGS. 1A to 1D are sectional views showing a conventional method of manufacturing a semiconductor device;

FIGS. 2A to 2C are sectional views showing the problem of conventional method;

FIGS. 3A to 3H are sectional views showing a method of manufacturing a semiconductor device of a first embodiment of the present invention;

FIG. 4A is a sectional view for explaining states of a semiconductor substrate when an organic anti-reflection film and a polysilicon film are etched by using a photoresist layer as a mask;

FIGS. 4B and 4C are sectional views showing an example of a process of using a hard mask;

FIG. 4D is a sectional view showing another example of a process of using a laminated hard mask layer;

FIGS. 5A to 5C are sectional views showing an advantage in a method of manufacturing the semiconductor device according to the first embodiment of the present invention;

FIGS. 6A to 6F are sectional views showing a method of manufacturing a semiconductor device according to a second embodiment of the present invention;

FIGS. 7A to 7M are sectional views showing a method of manufacturing a semiconductor device according to a third embodiment of the present invention; and

FIGS. 8A to 8L are sectional views showing the method of manufacturing the semiconductor device according to a fourth embodiment of the present invention.

### DESCRIPTION OF THE PREFERRED EMBODIMENTS

Hereinafter, a method of manufacturing a semiconductor device according to embodiments of the present invention will be described in detail with reference to the attached drawings.

### First Embodiment

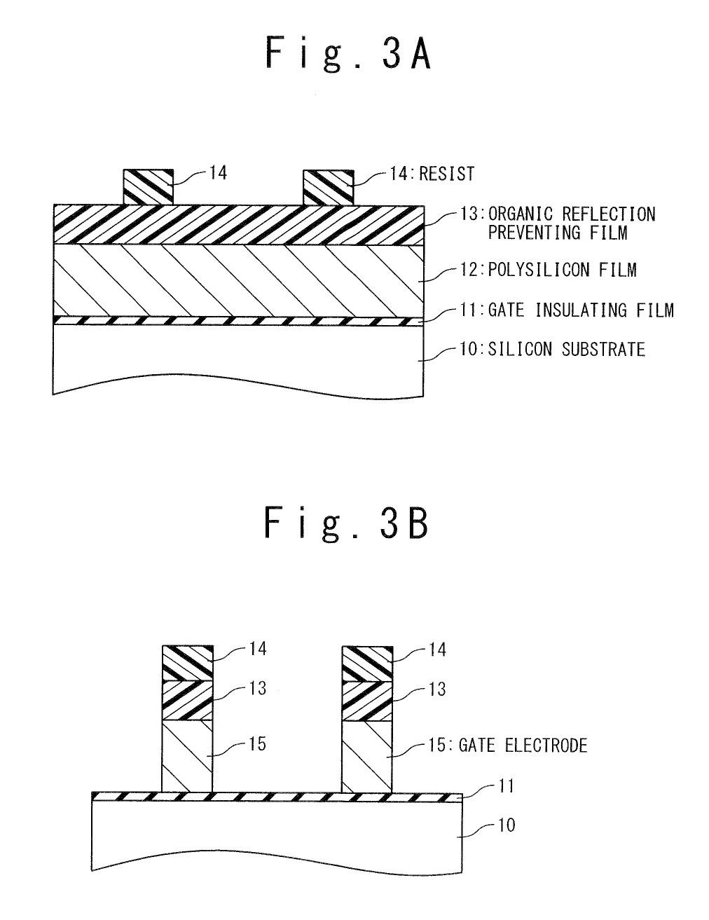

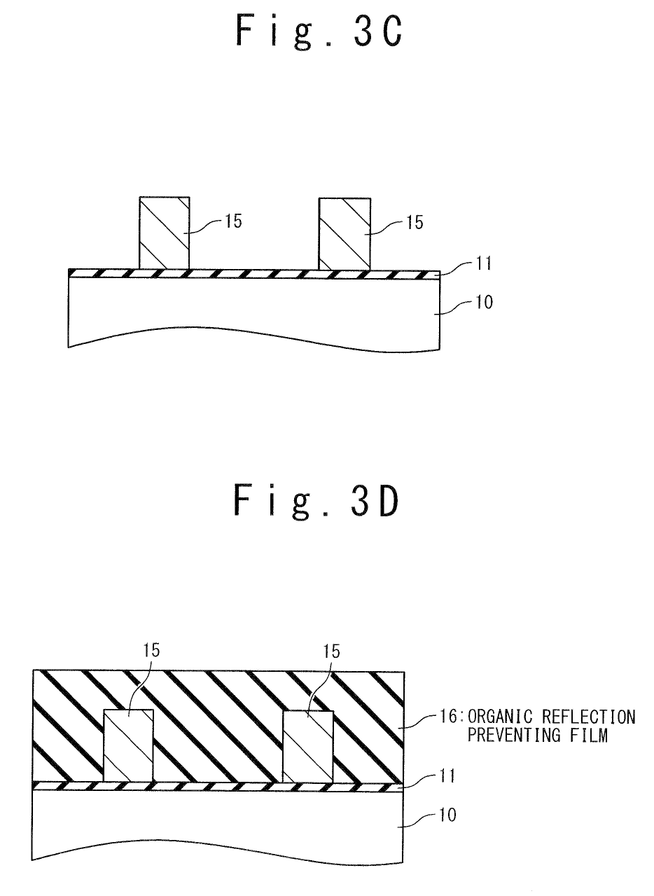

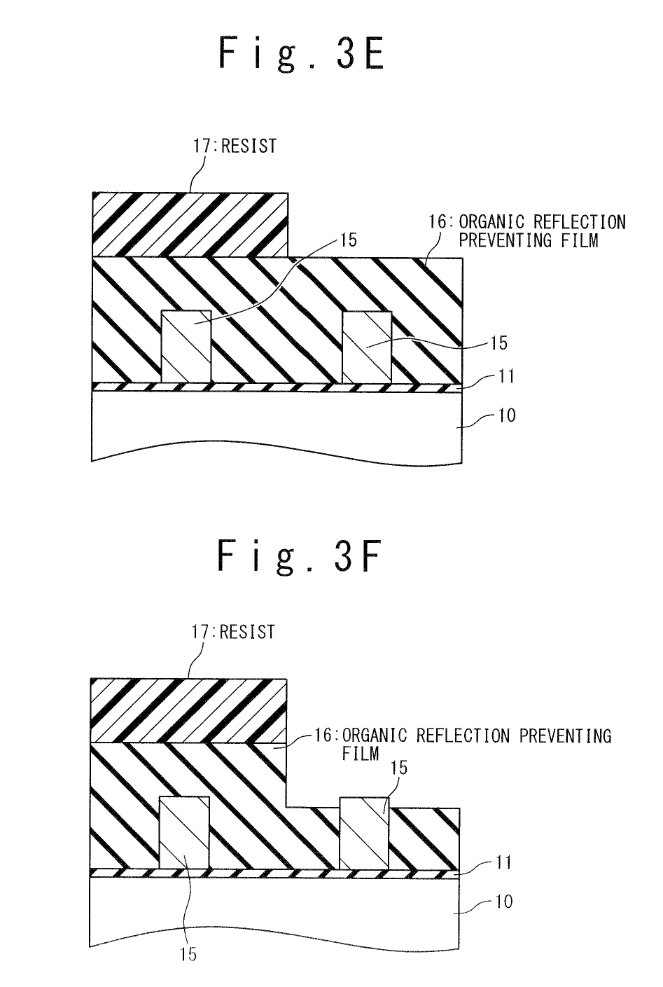

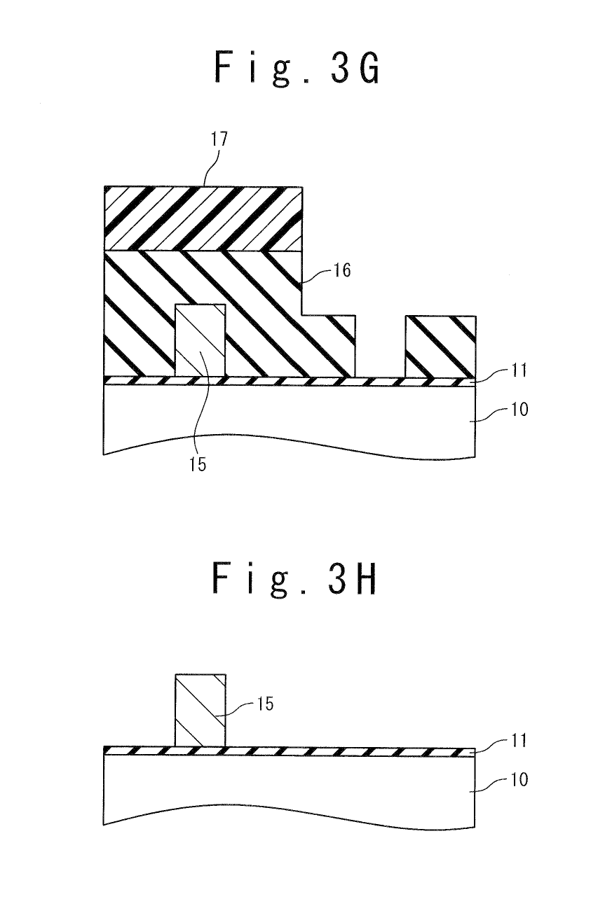

FIGS. 3A to 3H are sectional views showing a manufacturing method of a semiconductor device according to a first embodiment of the present invention. In the first embodiment, a process is performed in which a plurality of gate electrodes are formed, and further a part of them is selectively removed.

Specifically, as shown in FIG. 3A, a polysilicon film 12 and an organic anti-reflective film 13 are formed over a silicon substrate 10 that has been covered with a gate insulating film 11. A photoresist layer 14 is formed on the organic anti-reflective film 13 by a photolithography technique. The organic anti-reflective film 13 is made mainly of carbon.

Subsequently, as shown in FIG. 3B, the organic anti-reflective film 13 and the polysilicon film 12 are etched by using the photoresist layer 14 as a mask, and gate electrodes 15 are formed on the gate insulating film 11. Then, as shown in FIG. 3C, the photoresist layer 14 and the organic anti-reflective film 13 are removed by ashing and chemical treatment such as SPM washing.

After the photoresist layer 14 and the organic anti-reflective film 13 are removed, the whole surface of the silicon substrate 10 is covered with an organic anti-reflective film 16, as shown in FIG. 3D. Typically, the organic anti-reflective film 16 is formed by using a spin coating method. The concentration of a solution used for the spin coating is selected so that the top surface of the gate electrode 15 may not be exposed and the whole surface of the silicon substrate 10 is covered with the organic anti-reflective film 16.

Subsequently, as shown in FIG. 3E, a photoresist layer 17 is formed by the photolithography technique. The photoresist layer 17 is formed to cover the gate electrode 15 that will not be etched in a post process; an opening is provided above the gate electrode 15 that should be etched in the post process.

Subsequently, as shown in FIG. 3F, the organic anti-reflective film 16 is etched by using the photoresist layer 17 as a mask. This etching is performed until an upper part of the gate electrode 15 to be etched is exposed, and the organic anti-reflective film 16 is left on the gate insulating film 11. The etching of the organic anti-reflective film 16 is performed under the condition that the etching rate of the organic material of the organic anti-reflective film 16 becomes higher than the etching rate of the polysilicon of the gate electrode 15. Preferably, a mixed gas of O₂ and Cl₂ is used in etching the organic anti-reflective film 16 as an etching gas. O₂ functions as an etchant that mainly etches the organic anti-reflective film 16. Cl₂ has a function of removing a natural oxidation film formed on the surface of the gate electrode 15. In order to increase the etching selectivity of the organic anti-reflective film 16 to the gate electrode 15, it is desirable that the ratio of O₂ in the etching gas is higher, while the use of Cl₂ gas is effective to lessen the residue.

Subsequently, as shown in FIG. 3G, only the gate electrode 15 that was exposed through the previous etching is selectively etched. This etching is performed so that the organic anti-reflective film 16 may remain on the gate insulating film 11, and the gate electrode 15 is covered with the photoresist layer 17 and the organic anti-reflective film 16 is not etched. The etching of the gate electrode 15 is performed under the condition that the etching rate of the gate electrode 15 of the polysilicon film becomes higher than the etching rate of the organic material of the organic anti-reflective film 16. For the etching gas of the gate electrode 15, preferably a gas containing HBr is used. HBr functions as an etchant for etching polysilicon, and the use of pure HBr as an etchant gas can increase the etching selectivity of the gate electrode 15 to the photoresist layer 17 to be more than or equal to 10.

It is preferable to add a small amount of oxygen gas to the etching gas used in the etching the gate electrode 15. By adding the O₂ gas a little to the etching gas, it is possible to increase the etching selectivity of the gate electrode 15 to the gate insulating film 11, and thereby effectively protect the silicon substrate 10. However, it is undesirable from a viewpoint of leaving the organic anti-reflective film 16 and protecting the silicon substrate 10 that O₂ gas contained in the etching gas is excessively high. The ratio of O₂ gas in the etching gas of the gate electrode 15 is controlled to be low, compared with the ratio of O₂ gas in the etching gas of the organic anti-reflective film 16.

Moreover, in order to adjust the selectivity and the uniformity, it is also possible to add at least one of an inert gas such as He gas and Ar gas, a gas containing chlorine, and a gas containing fluorine such as fluorocarbon and SF₆ to the etching gas used in etching the gate electrode 15.

Subsequently, as shown in FIG. 3H, the organic anti-reflective film 16 and the photoresist layer 17 are removed. The removal of the organic anti-reflective film 16 and the photoresist layer 17 is performed through ashing, SPM washing, ozonization, or combinations thereof. By the above step, the process of forming the gate electrode 15 is completed. The organic anti-reflective film 16 and the photoresist layer 17 are easily removable by ashing, SPM washing, or ozonization. Therefore, according to the above process, the gate electrode 15 can be formed, while lessening etching residue.

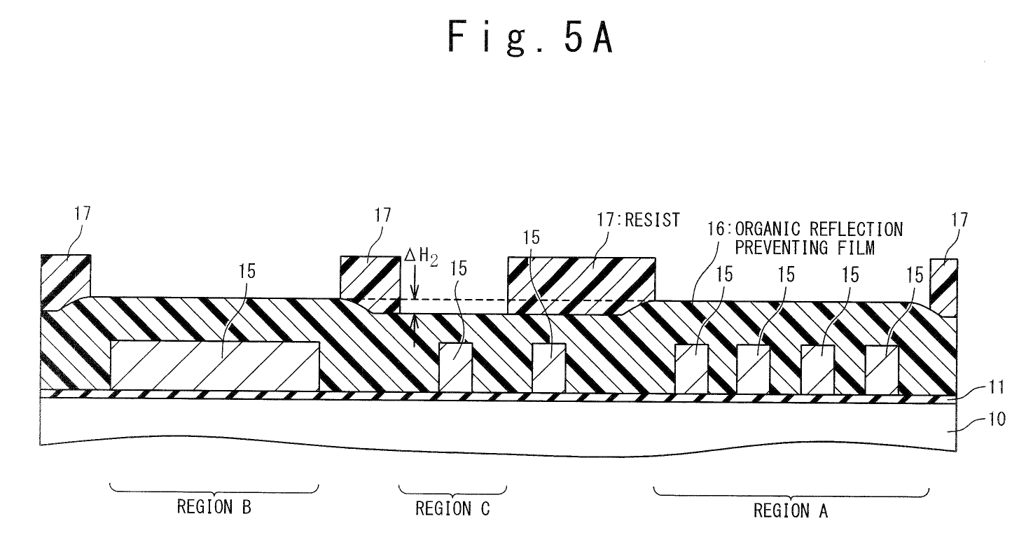

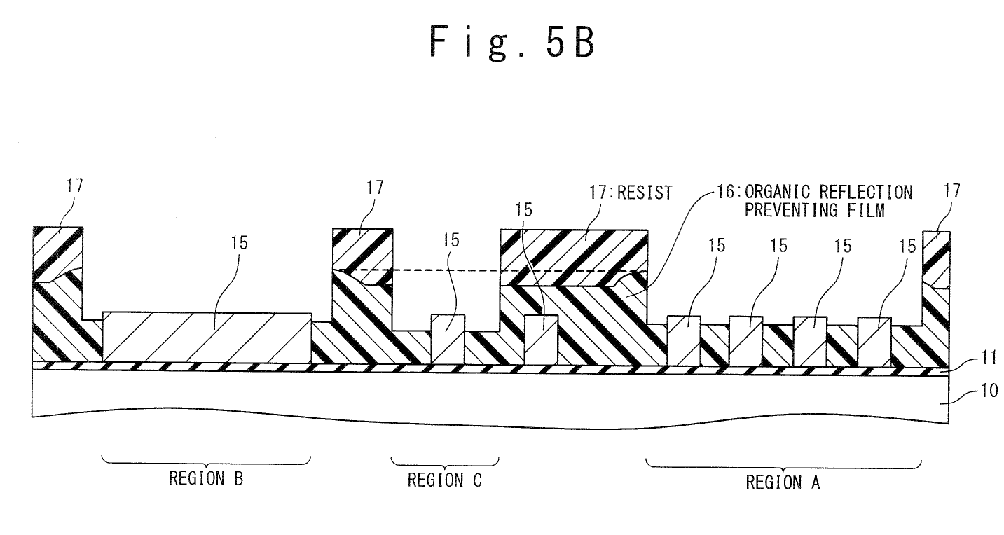

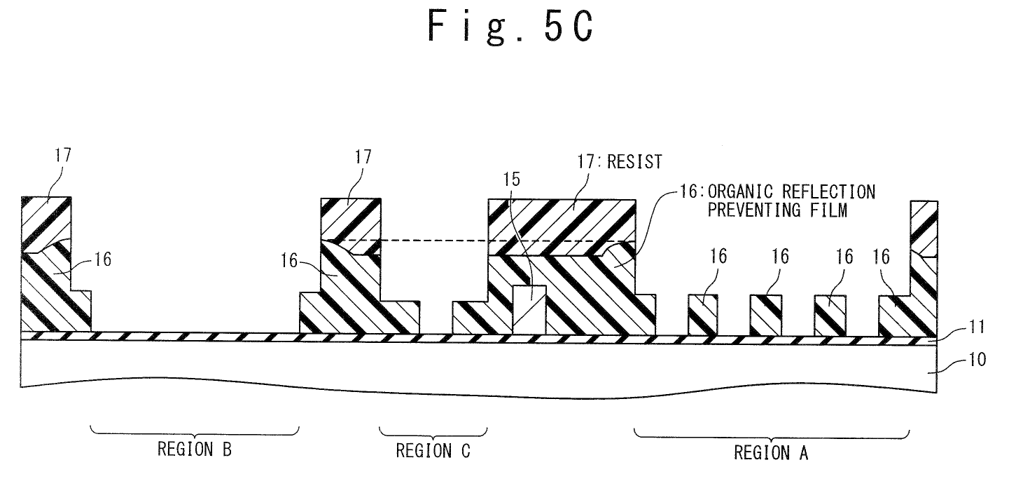

One of advantages of the manufacturing method of the semiconductor device of the present embodiment is that even when there are varieties of a packing density and a size of the gate electrode 15, the target gate electrode 15 can be selectively etched while protecting the silicon substrate 10. For example, a case is assumed in which the gate electrodes 15 located in the areas A to C of FIG. 5A are etched. It should be noted that in the area A, the packing density of the gate electrodes 15 is high; in the area B, the area of the gate electrode 15 is large; and in the area C, the area of the gate electrodes 15 is small. In the manufacturing method of the semiconductor device of the present embodiment, since the organic anti-reflective film 16 is covered over the whole surface of the silicon substrate 10, a difference ΔH₂ between the height of a top surface of the organic anti-reflective film 16 in the areas A (and B) and the height of the top surface of the organic anti-reflective film 16 in the area C is small, as shown in FIG. 5A. Therefore, even if there are varieties of the packing density and the size of the gate electrode 15, as shown in FIG. 5B, the upper parts of the gate electrodes 15 as a target of etching can be surely exposed with keeping the gate insulating film 11 covered by the organic anti-reflective film 16. Therefore, as shown in FIG. 5C, even if there are varieties of the packing density and the size of the gate electrode 15, the target gate electrodes 15 can be selectively etched while protecting the silicon substrate 10.

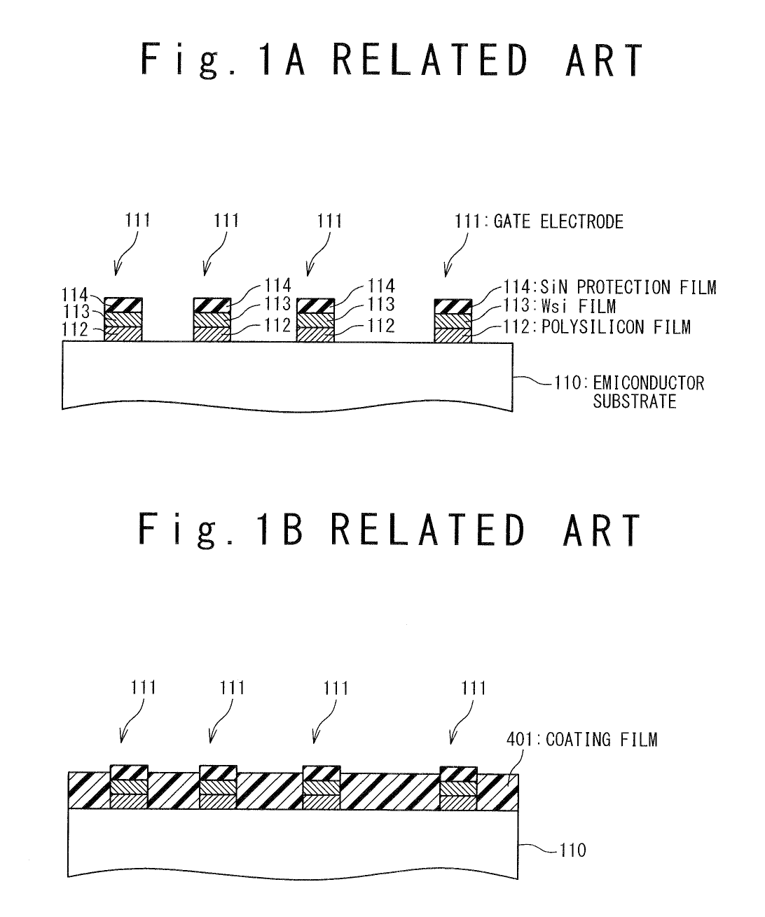

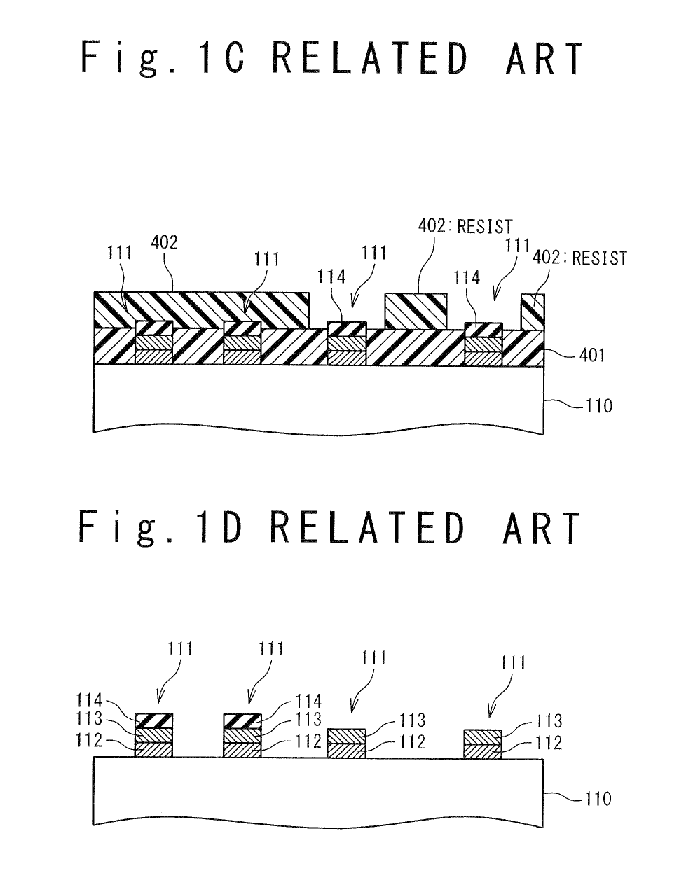

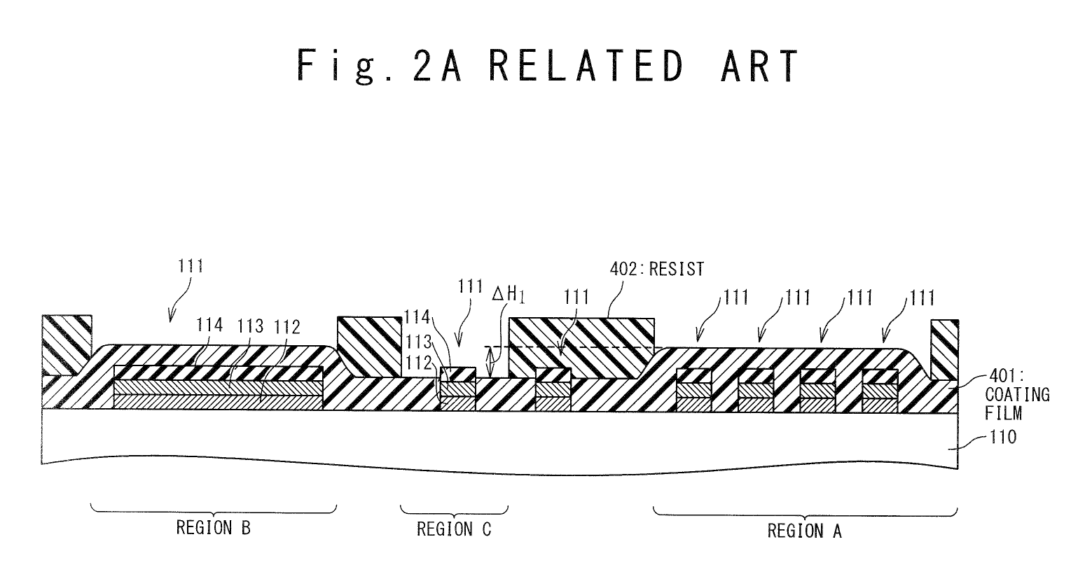

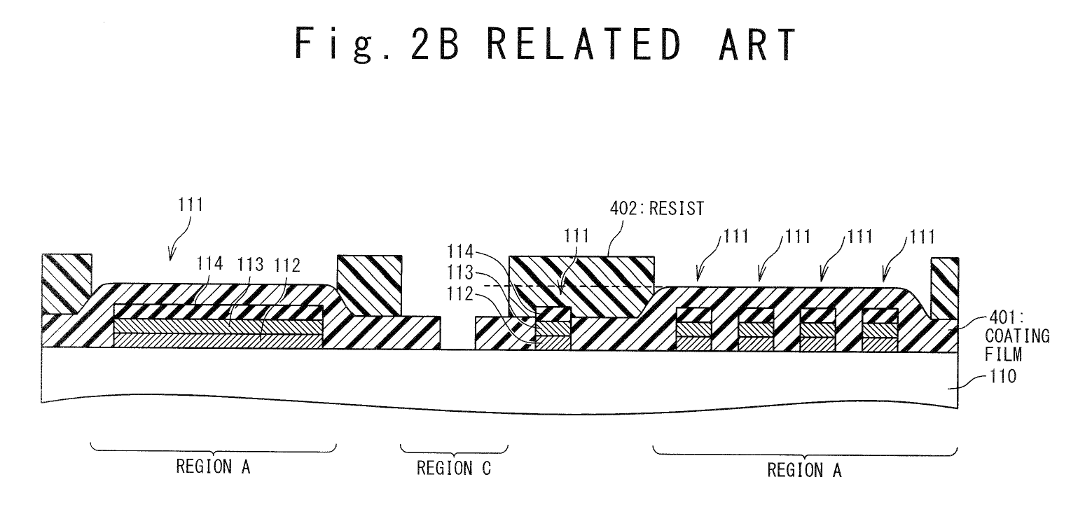

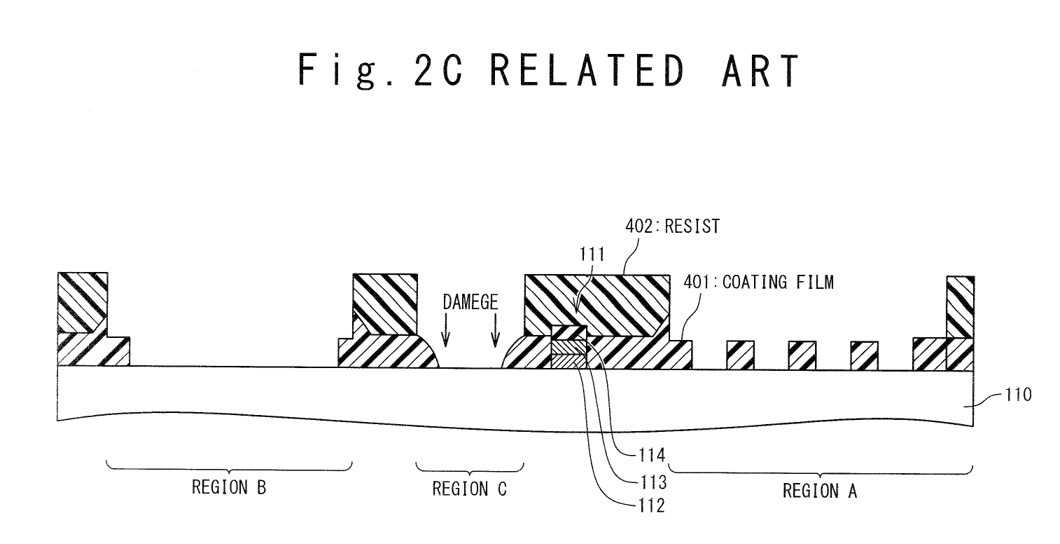

Another advantage of the manufacturing method of the semiconductor device of the present embodiment is in that, unlike the technique disclosed in the Japanese Laid Open Patent Application (JP-P2002-184860A), a problem of reflection is hard to occur in the photolithography process for forming the photoresist layer 17. As shown in FIG. 1C, by the technique disclosed in the Japanese Laid Open Patent Application (JP-P2002-184860A), the coating film 401 used as an anti-reflective film is covered only partially. If exposure is performed in a state covered only partially, a photoresist layer 402 in an undesired shape may be formed by reflection. This is because OPC (optical proximity correction) is generally performed by a premise that there is completely no reflection. On the other hand, in the manufacturing method of the semiconductor device of the present embodiment, since the organic anti-reflective film 16 is covered over the whole surface of the silicon substrate 10, a problem of reflection is hard to occur in the photolithography process for pattern forming the photoresist layer 17. Therefore, the photoresist layer 17 having a desired pattern shape can be formed according to the photolithography process.

In addition, in the present embodiment, it is also possible to use other organic films, for example, a polyimide film, instead of the organic anti-reflective film 16, from the viewpoint of protecting the silicon substrate 10. In this case, an anti-reflective film may be further formed on the organic film concerned. However, in order to avoid the problem of reflection in the photolithography process, it is preferable to use the organic anti-reflective film 16 for protecting the silicon substrate 10.

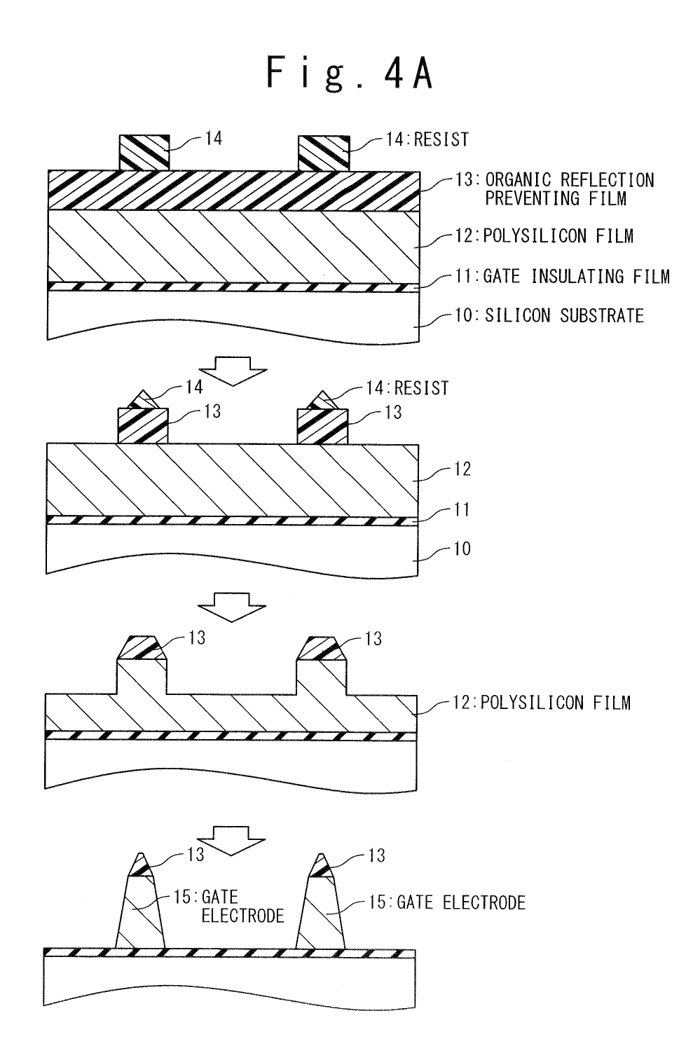

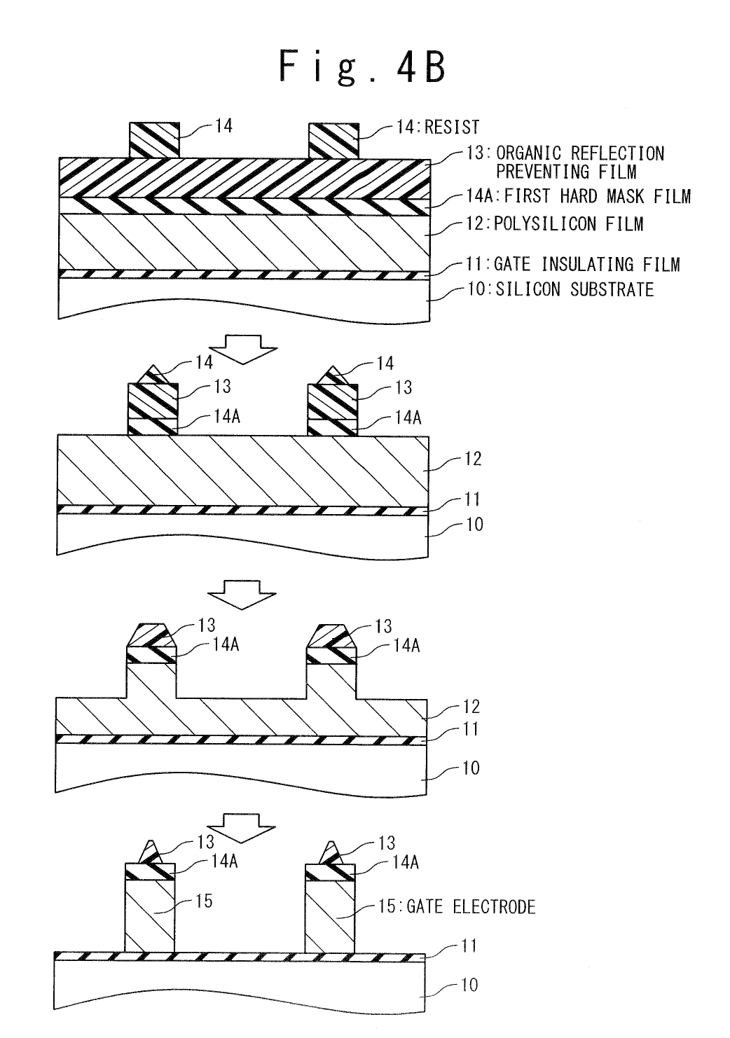

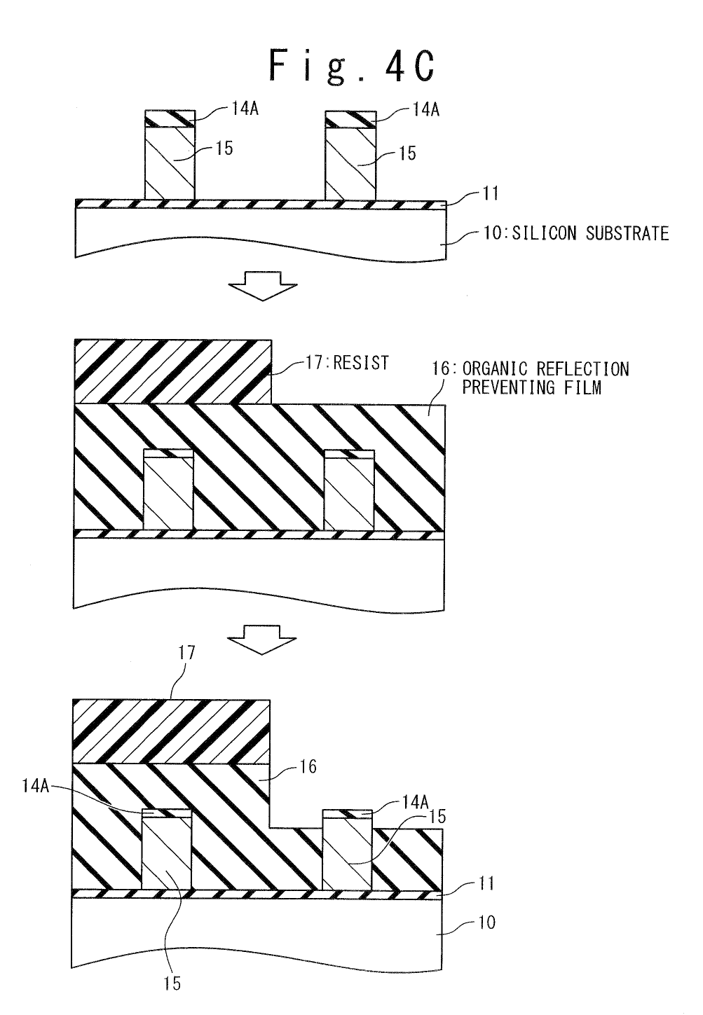

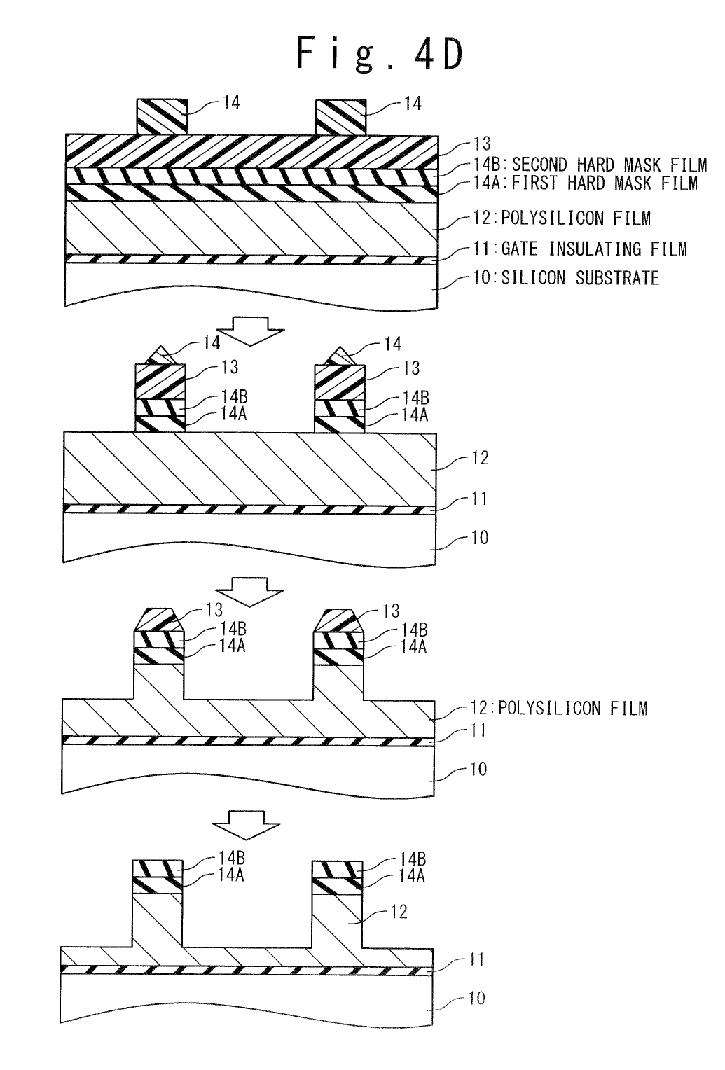

Moreover, in the manufacturing method of the semiconductor device of the present embodiment, it is also possible to use a hard mask formed of dielectric material. The most typical situation in which the hard mask is used is a case that a photoresist mask does not exhibit sufficient etching resistance. For example, as shown in FIG. 4A, it is supposed that the organic anti-reflective film 13 and the polysilicon film 12 are etched by using the photoresist layer 14 as a mask (uppermost portion in FIG. 4A). When the thickness of the photoresist layer 14 is thin or when the etching selectivity between the photoresist layer 14 and a film to be etched (namely, the organic anti-reflective film 13 and the polysilicon film 12) is not sufficient, the photoresist layer 14 and the organic anti-reflective film 13 becomes thin during the etching (second and third portions in FIG. 4A). For this reason, the gate electrodes 15 are formed in a trapezoidal shape with rounded shoulders (lowermost portion In FIG. 4A), which is undesirable. Below, a process of using the hard mask in order to form the gate electrode 15 in a desired shape will be explained.

FIGS. 4B and 4C are sectional views showing examples of a process of using the hard mask. In one example, a first hard mask layer 14A is formed on the polysilicon film 12 (uppermost portion in FIG. 4B). Since the first hard mask layer 14A is finally used as a mask in pattern formation of the gate electrode 15, it is formed of a material that can secure a high etching selectivity to the polysilicon film 12, for example, silicon oxide and silicon nitride. Further, the organic anti-reflective film 13 and the photoresist layer 14 are formed on the first hard mask 14A.

Subsequently, the organic anti-reflective film 13 is etched by using the photoresist layer 14 as a mask, and further, the first hard mask layer 14A is etched using the photoresist layer 14 and the organic anti-reflective film 13 as a mask (second portion in FIG. 4B). Moreover, the polysilicon film 12 is etched by using the first hard mask layer 14A (and the photoresist layer 14 and the organic anti-reflective film 13 if they remain) as a mask to form the pattern of the gate electrode 15. As shown in FIG. 4C, subsequently, the organic anti-reflective film 13 and the photoresist layer 14 are removed if they remain (uppermost portion in FIG. 4C).

The first hard mask layer 14A formed on the gate electrode 15 may be made to remain in order to be used as a protective film. For example, when a selective SiGe layer is epitaxially grown on a diffusion layer after the formation of the gate electrode 15, the SiGe layer does not grow on the first hard mask layer 14 that is left on the gate electrode 15. That is, the first hard mask layer 14 can be used as a protective film of inhibiting the growth of the SiGe layer. Below, a process in a case where the first hard mask layer 14A is made to remain on the gate electrode 15 will be described.

Subsequently, a process of removing a part of the plurality of formed gate electrodes 15 is performed. This process is usually called trim etching process. More specifically, after the whole surface of the substrate is covered with the organic anti-reflective film 16, the photoresist layer 17 is formed. After the pattern formation of the photoresist layer 17, the organic anti-reflective film 16 is partially etched by using the photoresist layer 17 as a mask (second portion in FIG. 4C), so that the first hard mask layer 14A formed on a top of the gate electrode 15 is exposed. This etching is performed under condition of attaching greater importance to uniformity.

After the first hard mask layer 14A is exposed, the exposed first hard mask layer 14A is etched while securing an etching selectivity to the organic anti-reflective film 16 which is more than or equal to one. When the first hard mask layer 14A is formed of silicon oxide, an etching gas is composed of a combination of CF gas (fluorocarbon gas) such as CF₄, C₄F₈, and C₅F₈, CHF gas (carbon fluorohydride gas) such as CHF₃, and CH₂F₂, an inert gas such as Ar and He, O₂ gas, and CO gas. The etching selectivity is adjusted by adjusting a composition of the etching gas. On the other hand, when the first hard mask layer 14A is formed of silicon nitride, an etching gas is composed of a combination of the CHF gas (carbon fluorohydride gas) such as CHF₃ and CH₂F₂, an inert gas such as Ar and He, and O₂ gas. The etching selectivity is adjusted by adjusting a composition of the etching gas.

After the gate electrode 15 is exposed by the etching of the first hard mask layer 14A, the exposed gate electrode 15 is etched while securing an etching selectivity thereof to the organic anti-reflective film 16. As described above, a gas containing HBr is preferably used for an etching gas of the gate electrode 15. It is preferable that a very small amount of oxygen is added to the etching gas used in etching of the gate electrode 15. Moreover, in order to adjust the etching selectivity and the uniformity, it is also possible for the etching gas used in etching the gate electrode 15 to add at least one gas among an inert gas such as He and Ar, a gas containing chlorine such as Cl₂, and a gas including fluorine such as SF₆ and fluorocarbon.

As shown in FIG. 4D, it is also possible to use a laminated hard mask of two layers. More specifically, the first hard mask layer 14A is formed on the polysilicon film 12, and the second hard mask layer 14B is formed on the first hard mask layer 14A. As described above, the hard mask layer 14A is formed of a material that the etching selectivity to the polysilicon film 12 can be secured, for example, silicon oxide or silicon nitride. Since the second hard mask layer 14B is used as a mask at the time of etching the first hard mask layer 14A, a material that the etching selectivity to the first hard mask layer 14A can be secured, for example, silicon (polysilicon or amorphous silicon) is used.

Subsequently, the organic anti-reflective film 13 is etched by using the photoresist layer 14 as a mask, and further, the second hard mask layer 14B is etched by using the photoresist layer 14 and the organic anti-reflective film 13 as a mask (a second field of FIG. 4D). Further, the first hard mask layer 14A is etched by using the second hard mask layer 14B (and the photoresist layer 14 and the organic anti-reflective film 13, if they remain) as a mask. Subsequently, the polysilicon film 12 is etched by using the first hard mask layer 14A as a mask, to form the gate electrode 15. The photoresist layer 14 and the organic anti-reflective film 13 are removed during when the first hard mask layer 14A is etched, and further, the second hard mask layer 14B is removed while the polysilicon film 12 is etched. As described above, the first hard mask layer 14A may be controlled to remain even after the pattern formation of the gate electrode 15. After this, a part of the plurality of the gate electrodes 15 is removed in the same manner as the case that a single layer hard mask (the first hard mask layer 14A) is used.

### Second Embodiment

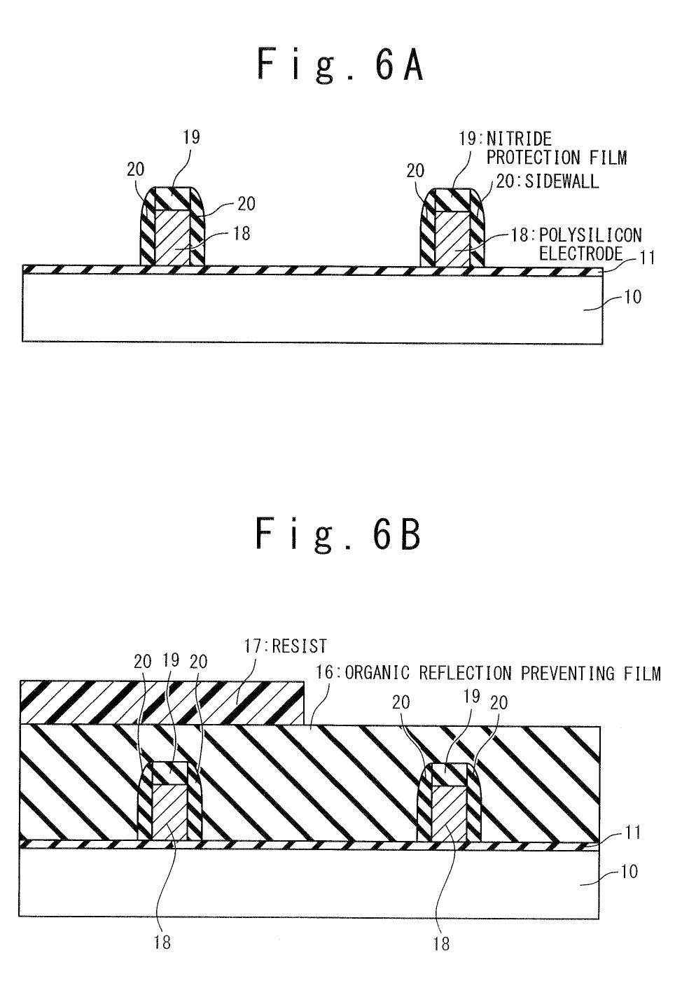

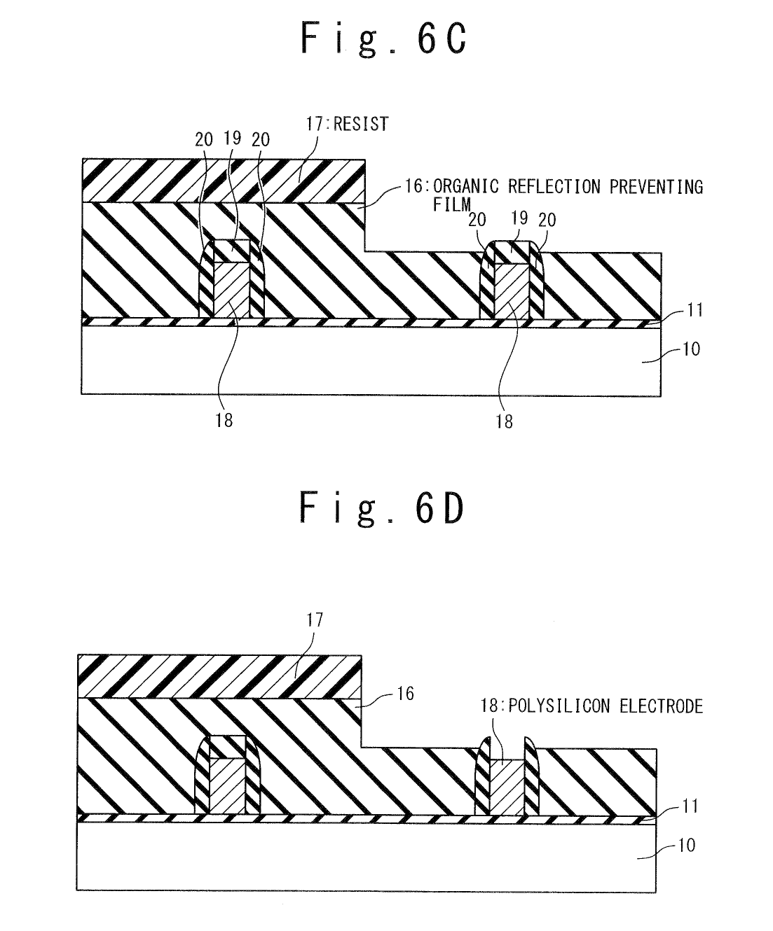

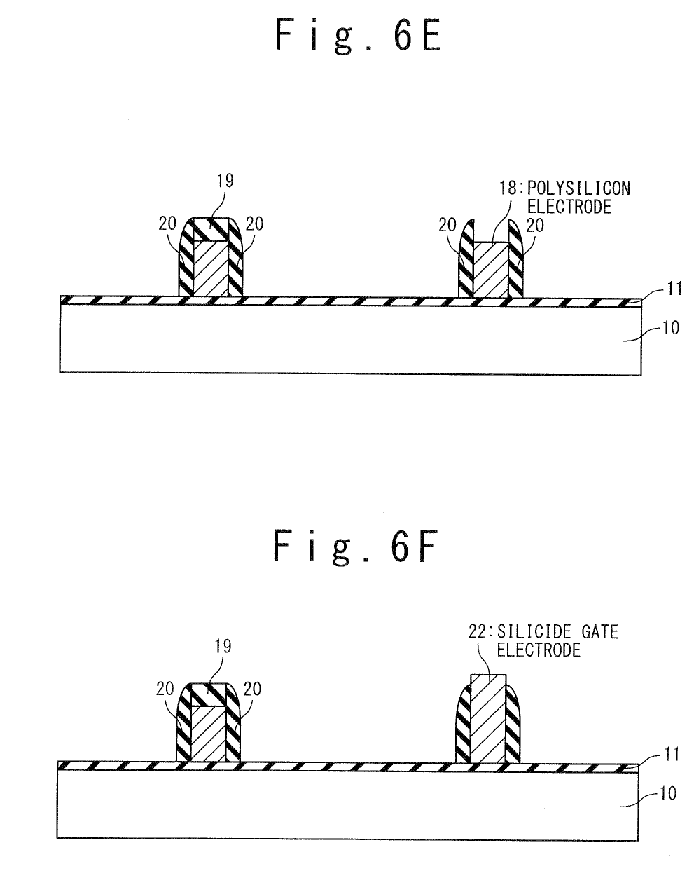

FIGS. 6A to 6F are sectional views showing a manufacturing method of a semiconductor device according to a second embodiment of the present invention. In the second embodiment, a process of selectively siliciding the polysilicon of a part of the gate electrodes is performed in a FUSI process.

In the second embodiment, as shown in FIG. 6A, a polysilicon electrode 18, a protection nitride film 19, and sidewalls 20 are formed over the silicon substrate 10 which is covered with the gate insulating film 11. The protection nitride film 19 is formed of silicon nitride, and plays a role of covering and protecting the polysilicon electrode 18. In the manufacturing method of the semiconductor device of the present embodiment, as will be described in detail later, the protection nitride film 19 formed on a part of the polysilicon electrodes 18 among the plurality of formed polysilicon electrodes 18 is selectively removed, and the part of polysilicon electrodes 18 are silicided.

More specifically, first, as shown in FIG. 6B, the whole surface of the silicon substrate 10 is covered with the organic anti-reflective film 16, and further, the patterned photoresist layer 17 is formed thereon by the photolithography technique. Typically, the organic anti-reflective film 16 is formed by using spin coating. The concentration of a solution used for the spin coating is selected so that the whole surface of the silicon substrate 10 may be covered with the organic anti-reflective film 16 without the protection nitride film 19 being exposed. The photoresist layer 17 is formed to cover an upper part of the protection nitride film 19 not to be removed in the post process, and the protection nitride film 19 to be removed in the post process is not covered with the photoresist layer 17.

Subsequently, as shown in FIG. 6C, the organic anti-reflective film 16 is etched by using the photoresist layer 17 as a mask. This etching is performed until the protection nitride film 19 to be removed is exposed, whereas the organic anti-reflective film 16 is left on the gate insulating film 11 after the etching. The etching of the organic anti-reflective film 16 is performed under the condition that an etching rate of the organic material of the organic anti-reflective film 16 becomes higher than that of the protection nitride film 19. Preferably, a mixed gas of O₂ and Cl₂ is used as an etching gas in etching the organic anti-reflective film 16. O₂ functions as an etchant for mainly etching the organic anti-reflective film 16.

Subsequently, as shown in FIG. 6D, only the protection nitride film 19 exposed through previous etching is selectively etched. The protection nitride film 19 covered with the photoresist layer 17 and the organic anti-reflective film 16 is not etched. The etching of the protection nitride film 19 is performed under the condition that the etching rate of the protection nitride film 19 becomes higher than that of the organic material of the organic anti-reflective film 16.

Preferably, fluorocarbon (namely, carbon fluorohydride having the composition formula of CₓH_{y}F_{z}) containing a hydrogen atom(s) is used as a material of the etching gas in etching the protection nitride film 19. More specifically, as the material of the etching gas for the protection nitride film 19, CHF₃, CH₂F₂, or CH₃F is used. By using fluorocarbon as the material of the etching gas, the protection nitride film 19 can be removed completely, while leaving the polysilicon electrode 18 and the organic anti-reflective film 16. By adding O₂ gas to the etching gas for the protection nitride film 19, the etching selectivity can be adjusted. However, an excessively high concentration of O₂ gas included in the etching gas is undesirable from a viewpoint of protecting the silicon substrate 10 by the organic anti-reflective film 16. The ratio of O₂ gas in the etching gas for the protection nitride film 19 is controlled low, as compared with the ratio of O₂ gas in the etching gas of the organic anti-reflective film 16.

Subsequently, as shown in FIG. 6E, the organic anti-reflective film 16 and the photoresist layer 17 are removed. The removal of the organic anti-reflective film 16 and the photoresist layer 17 is performed by ashing, SPM washing, ozonization, or combinations thereof. The removal can be easily performed, and therefore, according to the process as described above, the etching residue can be lessened. After the removal of the organic anti-reflective film 16 and the photoresist layer 17, only the polysilicon electrode 18 to be silicided is exposed. The polysilicon electrode 18 not to be silicided is remained covered with the protection nitride film 19.

Subsequently, as shown in FIG. 6F, the polysilicon electrode 18 that is not covered with the protection nitride film 19 is silicided to form a silicide gate electrode 22. Typically, siliciding of the polysilicon electrode 18 is performed by depositing a nickel film and then annealed. Through the above procedures, the process of selectively siliciding the target polysilicon electrode 18 is completed.

In the manufacturing method of the semiconductor device of the present embodiment, after the whole surface of the silicon substrate 10 is covered with the organic anti-reflective film 16, the organic anti-reflective film 16 is partially etched, such that only the protection nitride film 19 to be etched is selectively exposed. According to the process like this, even if there are varieties of the packing density and the size of the polysilicon electrodes 18, it is possible to selectively etch a target part of the protection nitride film 19 while protecting the silicon substrate 10. In addition, since the organic anti-reflective film 16 covers the whole surface of the silicon substrate 10, the photoresist layer 17 in a desired shape can be formed without causing a problem of reflection in the photolithography process for patterning the photoresist layer 17.

### Third Embodiment

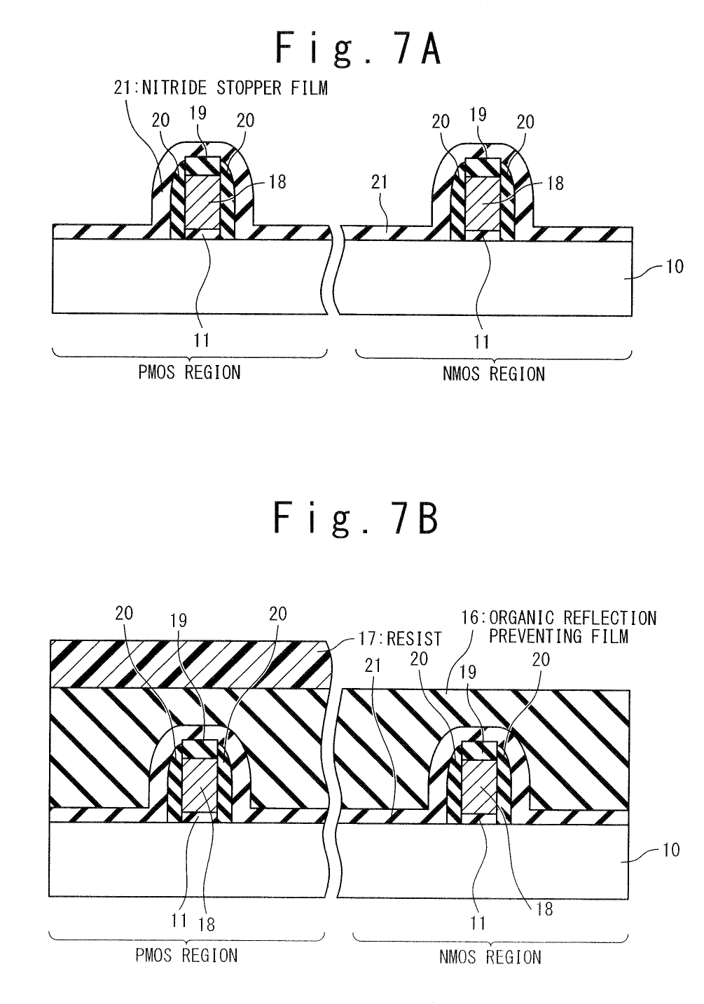

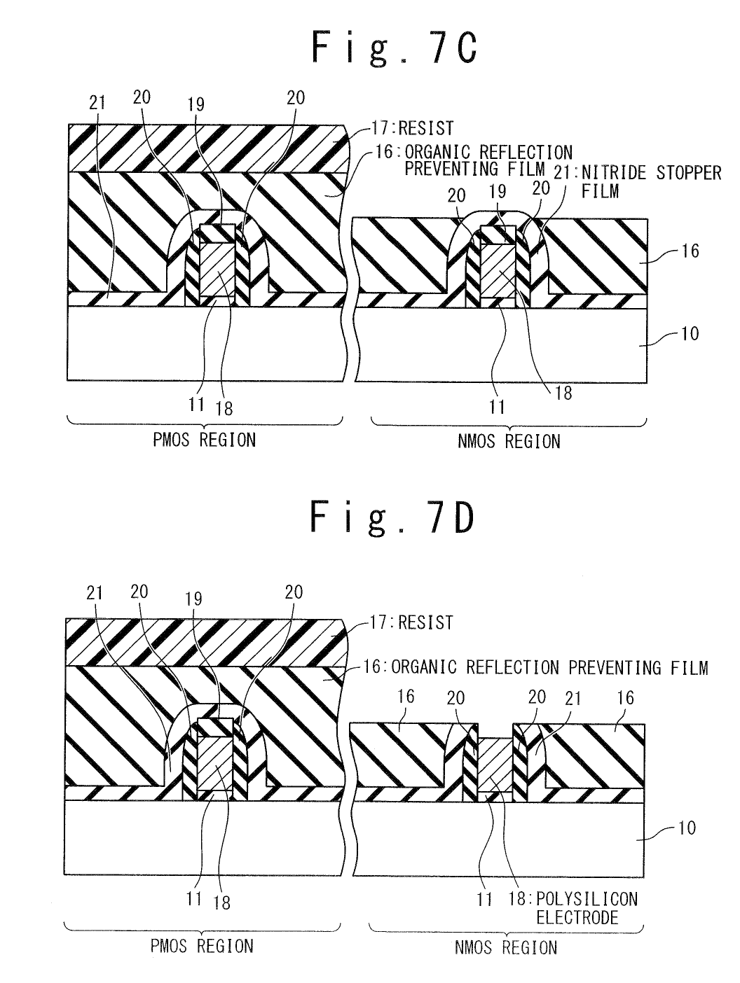

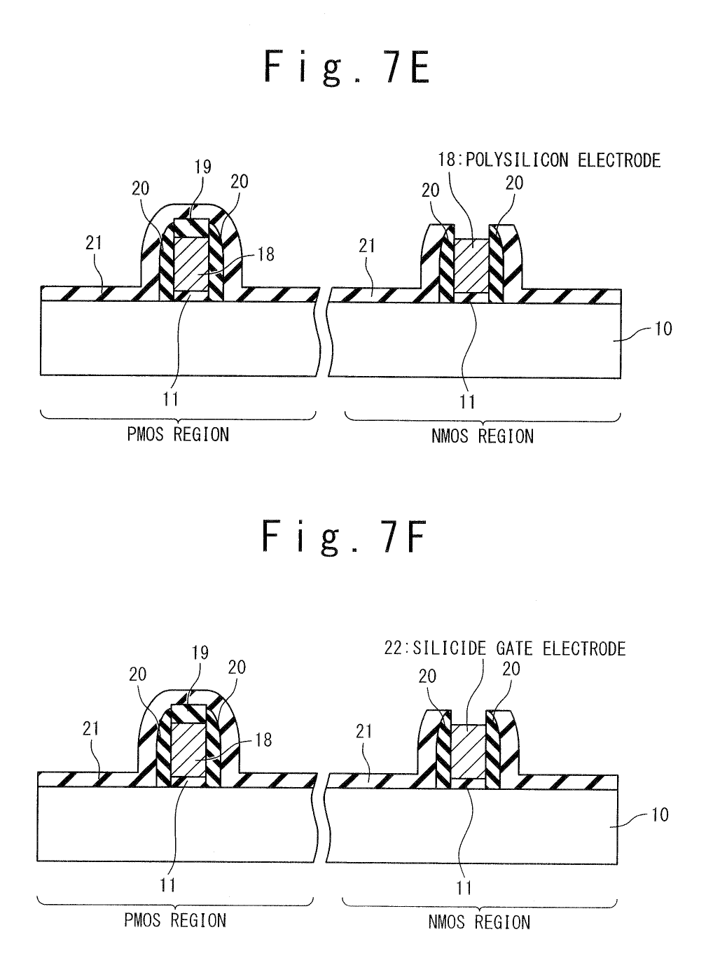

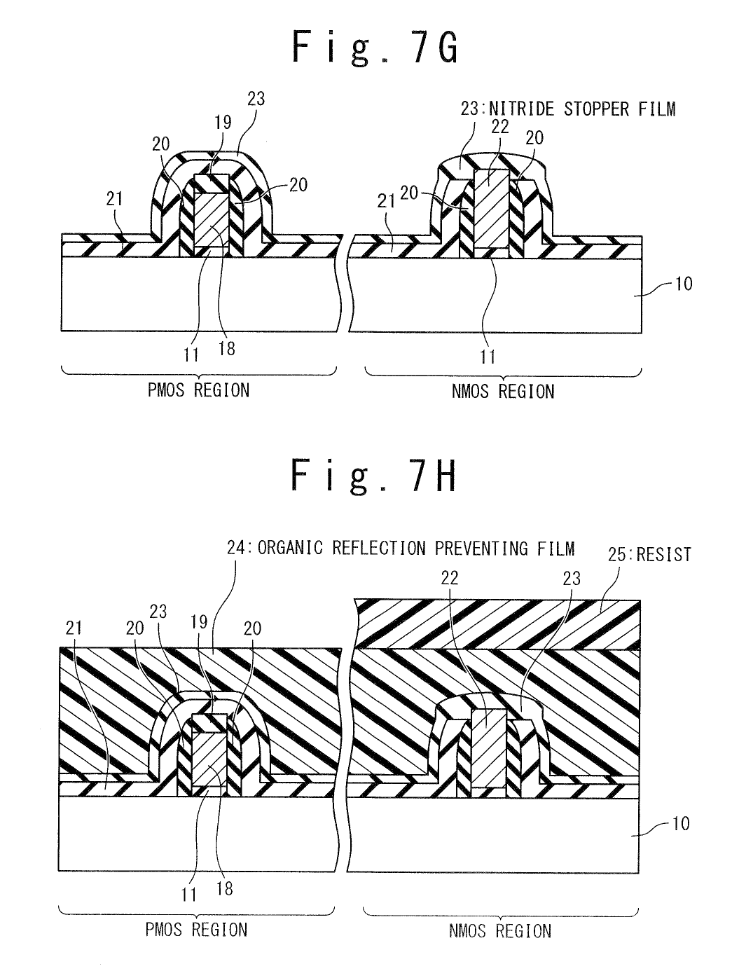

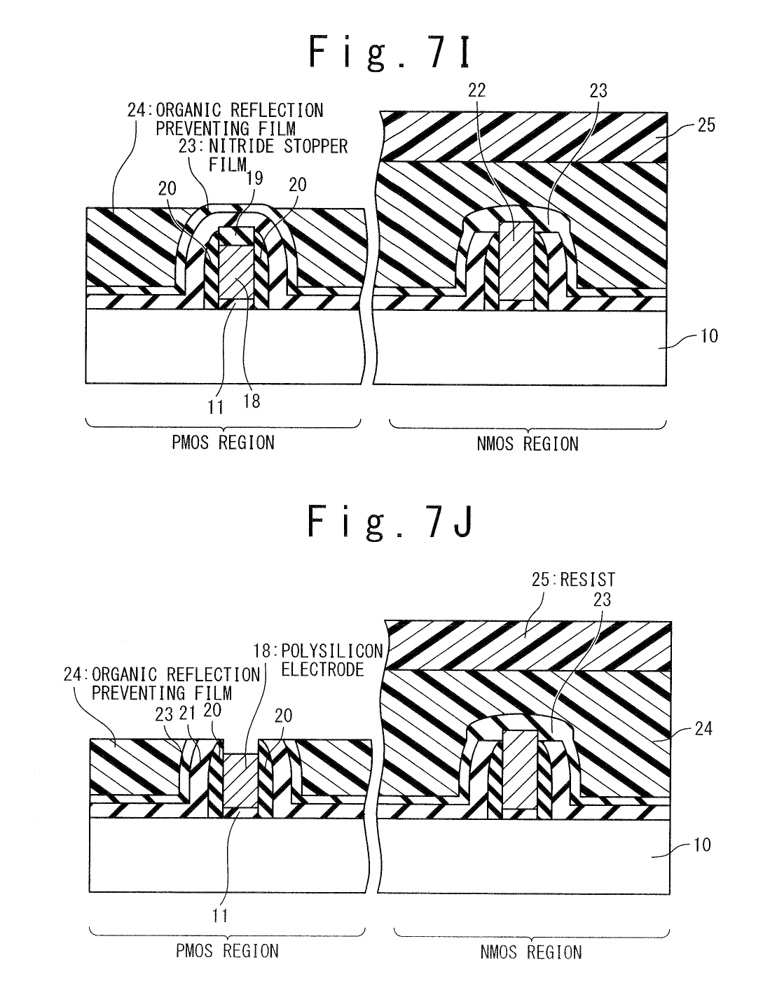

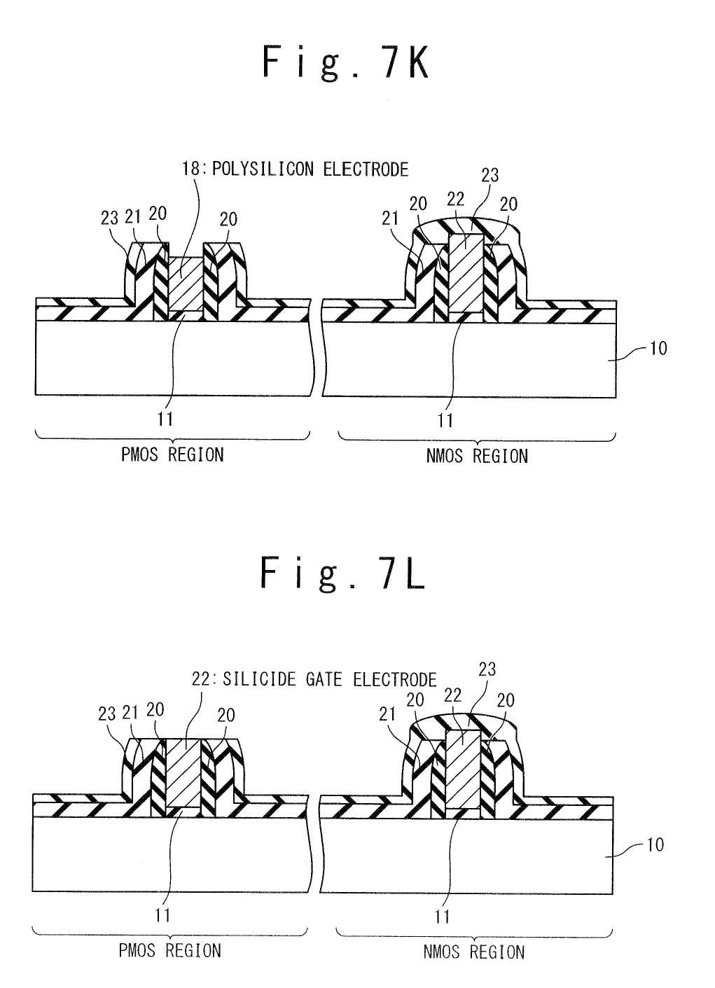

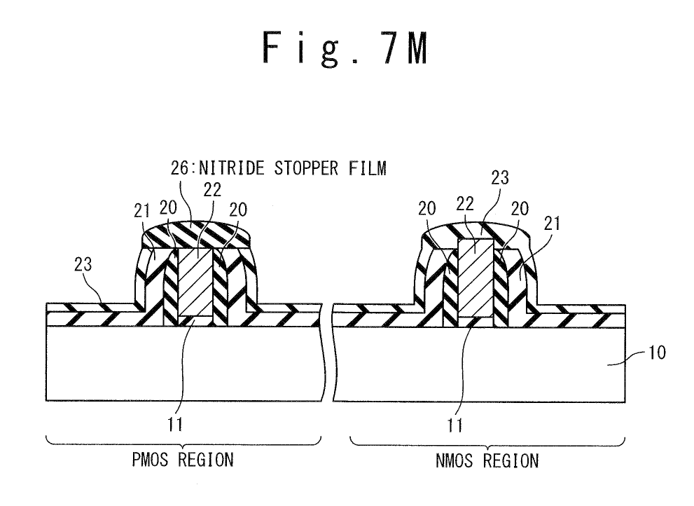

FIGS. 7A to 7M are sectional views showing a manufacturing method of a semiconductor device in a third embodiment of the present invention. In the third embodiment, when the whole surface of the silicon substrate 10 is covered with a stopper nitride film 21 made of silicon nitride as shown in FIG. 7A, a process is performed in which the polysilicon electrode 18 in an NMOS area and that in a PMOS area are separately silicided. The polysilicon electrode 18 is used as the gate electrode of a MOS transistor after siliciding is performed. As could be understood easily by a person skilled in the art, a reason why the NMOS area and the PMOS area of the polysilicon electrodes 18 are subjected to siliciding separately is to control a work function of the gate electrode formed by the siliciding.

The stopper nitride film 21 has three functions. A first function is to protect the silicon substrate 10 during the pattern formation of the polysilicon electrode 18 has been performed. A second function is a function as an etching stopper in case of forming self-aligned contact. A third function is to increase the mobility of carriers by applying a suitable stress to the silicon substrate 10, thereby improving performance of the MOS transistor.

According to study of the inventors, in order to realize the third function, it is necessary for the whole surface of the gate electrode to be covered with the silicon nitride film. On the other hand, in order to silicide the polysilicon electrode 18, it is necessary to remove both of the protection nitride film 19 and the stopper nitride film 21 formed on or over the polysilicon electrode 18. From these reasons, in the present embodiment, after a part of the stopper nitride film 19 is temporarily removed, a process of covering the whole surface of the silicon substrate 10 again with the silicon nitride film is performed.

More specifically, first, a process of siliciding the polysilicon electrode 18 in the NMOS area is performed. To be in detail, first, the whole surface of the silicon substrate 10 is covered with the organic anti-reflective film 16, and the photoresist layer 17 is patterned by the photolithography technique, as shown in FIG. 7B. The photoresist layer 17 is formed to cover the PMOS area. Typically, the organic anti-reflective film 16 is formed by spin coating. The concentration of a solution used for spin coating is selected so that the stopper nitride film 21 is not exposed, and the whole surface of the silicon substrate 10 is covered with the organic anti-reflective film 16.

Subsequently, as shown in FIG. 7C, the organic anti-reflective film 16 is etched using the photoresist layer 17 as a mask. This etching is performed until a part of the stopper nitride film 21 is exposed in the NMOS area, whereas the organic anti-reflective film 16 is left on the gate insulating film 11. The etching of the organic anti-reflective film 16 is performed under the condition that the etching rate of the organic material of the organic anti-reflective film 16 becomes considerably higher than the etching rate of the silicon nitride film. Preferably, a mixed gas of O₂ and Cl₂ is used as the etching gas used for etching the organic anti-reflective film 16.

Subsequently, as shown in FIG. 7D, for the NMOS area, a part of the stopper nitride film 21 that covers the protection nitride film 19 and the protection nitride film 19 is selectively etched. In the PMOS area, the stopper nitride film 21 and the protection nitride film 19 are not etched. The etching is performed until the protection nitride film 19 in the NMOS area is removed completely. The etching of the stopper nitride film 21 and the protection nitride film 19 is performed under the condition that the etching rate of the silicon nitride film becomes considerably higher than that of the organic material of the organic anti-reflective film 16.

Preferably, fluorocarbon including a hydrogen atom(s), such as CHF₃, CH₂F₂, and CH₃F is used as a material of an etching gas in etching both of the stopper nitride film 21 and the protection nitride film 19, as in second embodiment. The use of fluorocarbon for the etching gas allows the protection nitride film 19 formed on the polysilicon electrode 18 to be removed completely, with leaving the polysilicon electrode 18 and the organic anti-reflective film 16. The etching selectivity can be adjusted by adding O₂ gas to the etching gas of the stopper nitride film 21 and the protection nitride film 19. However, from a viewpoint of leaving the organic anti-reflective film 16 to protect the silicon substrate 10, it is undesirable that a ratio of O₂ gas included in the etching gas is excessively high. The ratio of O₂ in the etching gas of the stopper nitride film 21 and the protection nitride film 19 is controlled low, as compared with the ratio of O₂ gas in the etching gas of the organic anti-reflective film 16.

Subsequently, as shown in FIG. 7E, the organic anti-reflective film 16 and the photoresist layer 17 are removed. The removal of the organic anti-reflective film 16 and the photoresist layer 17 is performed by ashing, SPM washing, ozonization, or combinations thereof. The removal is easy, and therefore according to a process as described above, the etching residue can be lessened. After the removal of the organic anti-reflective film 16 and the photoresist layer 17, only the polysilicon electrode 18 located in the NMOS area is exposed. The polysilicon electrode 18 located in the PMOS area is covered with the stopper nitride film 21 and the protection nitride film 19.

Subsequently, as shown in FIG. 7F, the polysilicon electrode 18 in the NMOS area is silicided to form the silicide gate electrode 22. Typically, siliciding of the polysilicon electrode 18 is performed by depositing the nickel film and successive annealing. By the above procedure, the process of selectively siliciding the polysilicon electrode 18 in the NMOS area is completed.

Subsequently, as shown in FIG. 7G, the whole surface of the silicon substrate 10 is covered with a stopper nitride film 23. It is preferable for the stopper nitride film 23 to be formed so that its thickness may become large only above the polysilicon electrode 18 in the NMOS area. In order to form the stopper nitride film 23 like this, it is preferable that after the silicon nitride film having a thick thickness is formed, a part other than a part above the polysilicon electrode 18 in the NMOS area is etched.

Subsequently, a process of siliciding the polysilicon electrode 18 in the PMOS area is performed. Specifically, as shown in FIG. 7H, first, the whole surface of the silicon substrate 10 is covered with an organic anti-reflective film 24, and further, a photoresist layer 25 is formed and then patterned by the photolithography technique. The photoresist layer 25 is formed to cover the NMOS area. Typically, an organic anti-reflective film 24 is formed by using spin coating. The concentration of a solution used for spin coating is selected so that the upper part of the stopper nitride film 23 may not be exposed and the whole surface of the silicon substrate 10 is covered with the organic anti-reflective film 24.

Subsequently, as shown in FIG. 7I, the organic anti-reflective film 16 is etched using the photoresist layer 25 as a mask. This etching is performed until the upper part of the stopper nitride film 23 is exposed in the PMOS area, with leaving the organic anti-reflective film 24 on the gate insulating film 11. The etching of the organic anti-reflective film 16 is performed under the condition that an etching rate of an organic material of the organic anti-reflective film 24 becomes considerably higher than that of the silicon nitride film. Preferably, a mixed gas Of O₂ and Cl₂ is used as an etching gas for etching the organic anti-reflective film 24.

Subsequently, as shown in FIG. 7J, the stopper nitrides 23 and 21 located in the PMOS area and the protection nitride film 19 are selectively etched. The stopper nitride films 21 and 23 formed in the NMOS area are not etched. The etching is performed until the protection nitride film 19 in the PMOS area is removed completely. The etching of the stopper nitride films 21 and 23 and the protection nitride film 19 is performed under the condition that the etching rate of the silicon nitride film becomes considerably higher than that of the organic material of the organic anti-reflective film 24.

Subsequently, as shown in FIG. 7K, the organic anti-reflective film 24 and the photoresist layer 25 are removed. The removal of the organic anti-reflective film 24 and the photoresist layer 25 is performed by ashing, SPM washing, ozonization, or combinations thereof. After the removal of the organic anti-reflective film 24 and the photoresist layer 25, the polysilicon electrode 18 located in the PMOS area is exposed. The silicide gate electrode 22 located in the NMOS area has been covered with the stopper nitride film 23.

Subsequently, as shown in FIG. 7L, the polysilicon electrode 18 in the PMOS area is silicided to form the silicided gate electrode 22. Typically, the siliciding of the polysilicon electrode 18 is depositing by forming and successive annealing. Through the above process, the process of selectively siliciding the polysilicon electrode 18 in the PMOS area is completed.

Subsequently, a stopper nitride film 26 that covers the silicide gate electrode 22 in the PMOS area is formed as shown in FIG. 7M. The stopper nitride films 21, 23, and 26 are formed, so that the whole surface of the silicon substrate 10 will be covered with the silicon nitride film. This process is effective to apply suitable stress to the silicon substrate 10 and thereby increase the mobility of carriers. Through the above process, the siliciding of the polysilicon electrode 18 is completed.

It should be noted that in the manufacturing method of the semiconductor device of the present embodiment, silicidization of the polysilicon electrode is performed by separate processes in the NMOS area and in the PMOS area. This is for making the threshold of the MOS transistor controllable individually in the NMOS area and in the PMOS area. For example, by siliciding the NMOS area and the PMOS area by separate processes, the film thickness of a nickel thin film used for silicidization of the polysilicon electrode can be made different. By adjusting the thickness of the nickel thin film individually, a composition of the silicide gate electrode can be adjusted individually, and thereby the threshold of the MOS transistor can be individually controlled in the NMOS area and in the PMOS area. Moreover, in a state that the polysilicon electrode is exposed (for example, immediately before the nickel thin film) or in a state that the silicide gate is exposed (for example, immediately after the silicidization), by implanting impurity under the conditions suitable in the NMOS area and in the PMOS area, respectively, the threshold of the MOS transistor can be controlled individually in the NMOS area and in the PMOS area.

As described above, in the manufacturing method of the semiconductor device of the present embodiment, after the organic anti-reflective films 16 and 24 are formed to cover the whole surface of the silicon substrate 10, the organic anti-reflective films 16 and 24 are partially etched and part of the stopper nitride films 21 and 23 to be etched is selectively exposed. According to such a process, even if there are varieties of the packing density and the size of the polysilicon electrode 18, target parts of the stopper nitride films 21 and 23 and the protection nitride film 19 located thereunder can be selectively etched while protecting the silicon substrate 10. In addition, since the organic anti-reflective films 16 and 24 cover the whole surface of the silicon substrate 10, the photoresist layers 17 and 25 can be formed in a desired shape without causing the problem of reflection in the photolithography process for patterning the photoresist layers 17 and 25.

### Fourth Embodiment

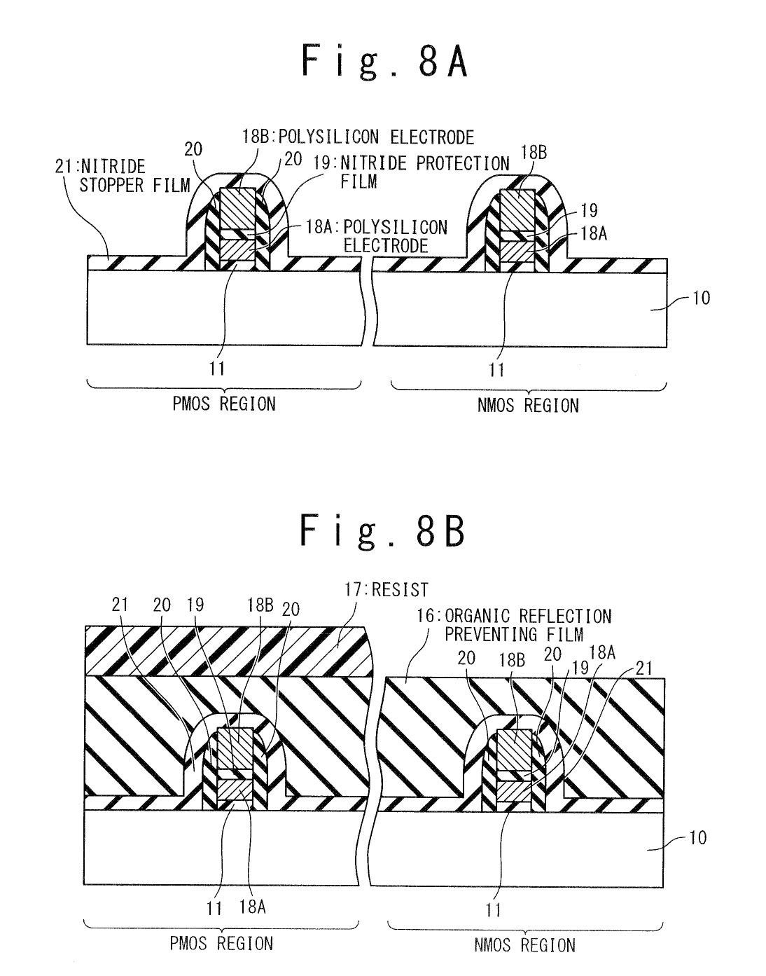

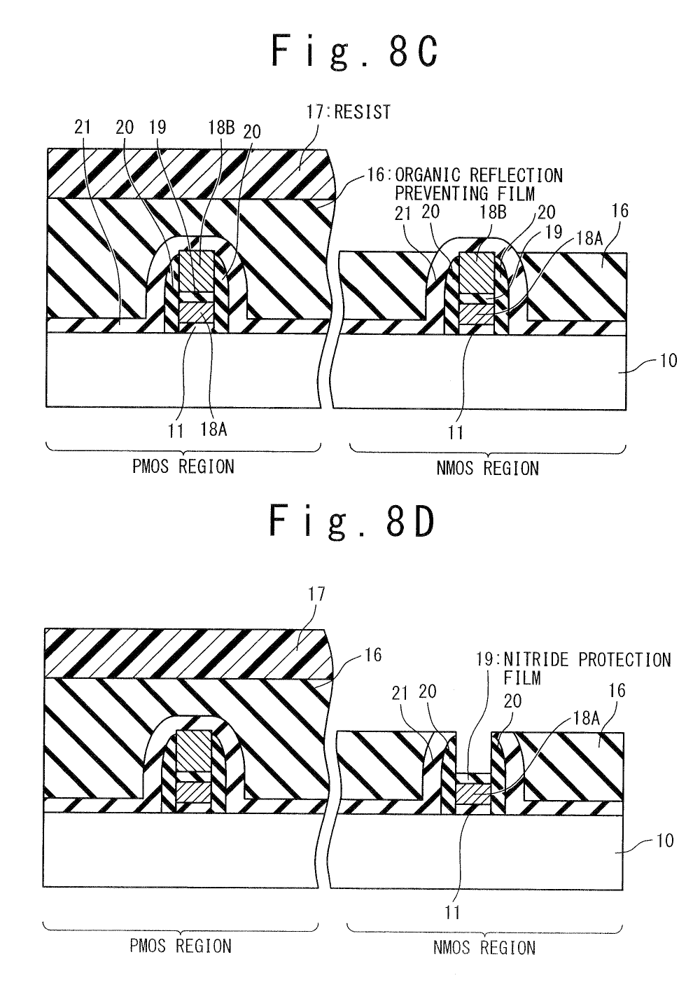

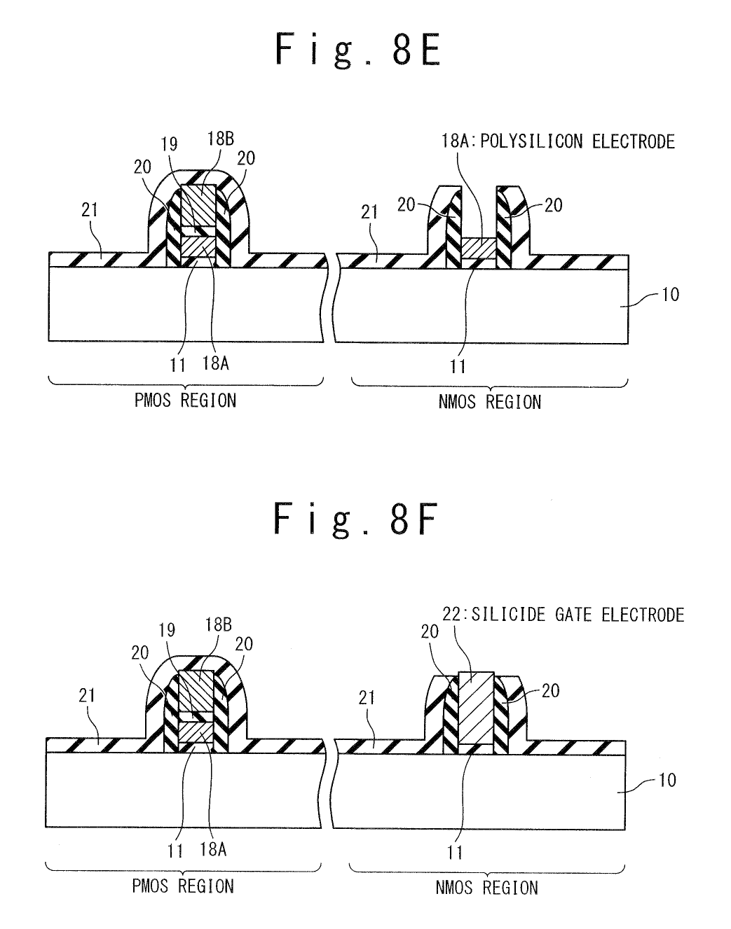

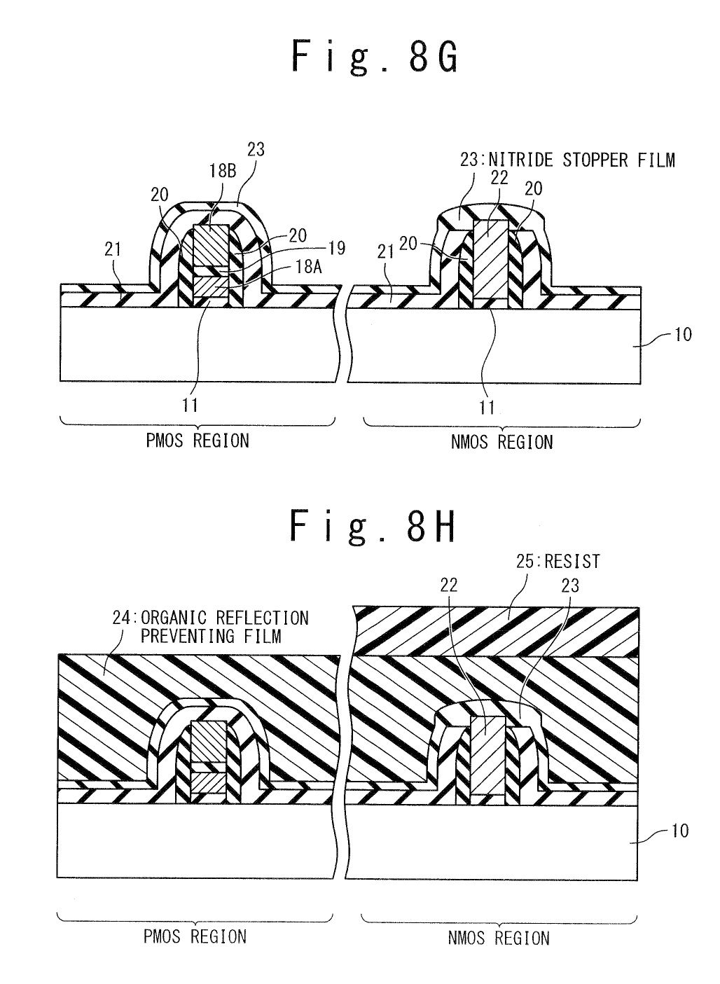

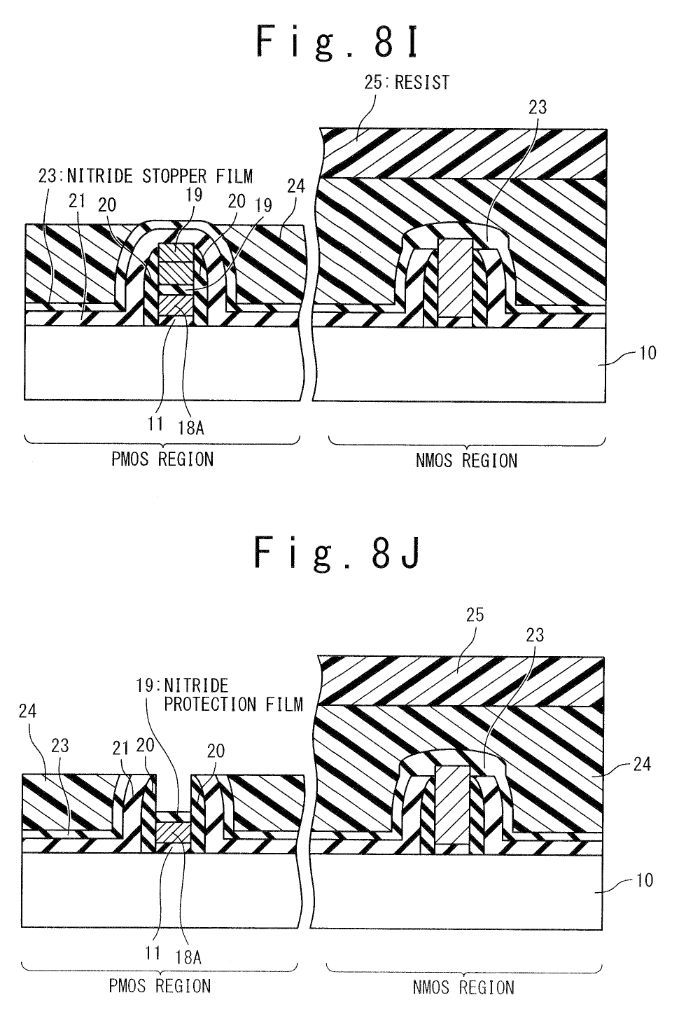

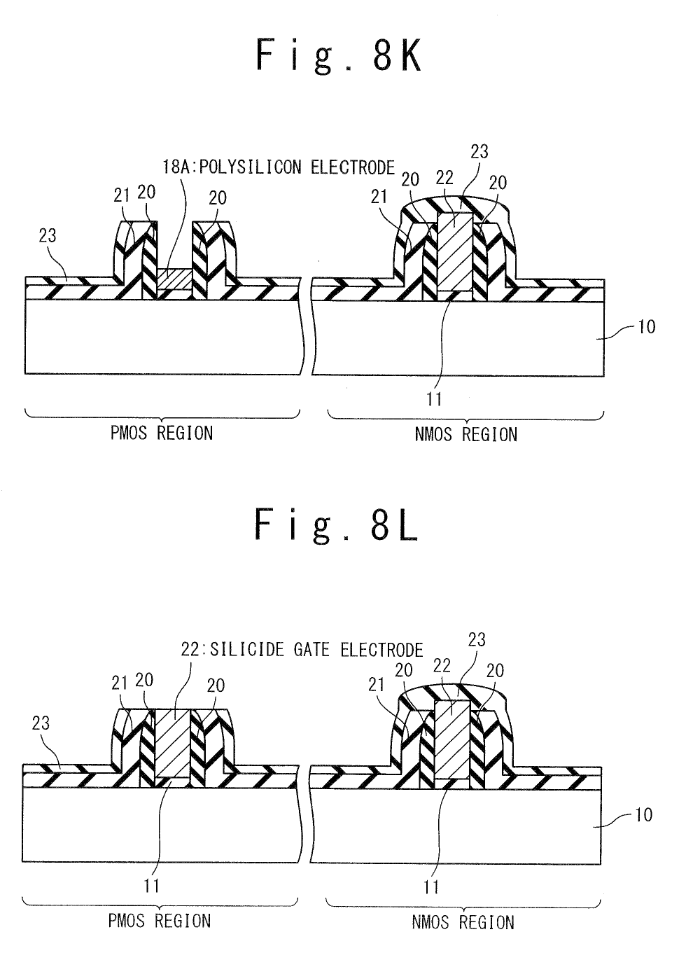

FIGS. 8A to 8L are sectional views showing a manufacturing method of a semiconductor device in a fourth embodiment of the present invention. The manufacturing method of the semiconductor device in the fourth embodiment is almost the same as the manufacturing method of the semiconductor device of the third embodiment. A difference is in that, as shown in FIG. 8A, two-layer polysilicon electrodes 18A and 18B are formed on the gate insulating film 11, and the protection nitride film 19 is formed therebetween. In the fourth embodiment, only the polysilicon electrode 18A is silicided among the polysilicon electrodes 18A and 18B. That is, the polysilicon electrode 18B is removed before the silicidization of the polysilicon electrode 18A. The reason of adopting such a process is to control a composition ratio of silicon contained in the silicide gate electrode formed by the silicidization and a metal element (for example, nickel). By controlling the composition ratio of silicon and the metallic element, a work function of the silicide gate electrode can be controlled.

More specifically, first, the polysilicon electrode 18B and the protection nitride film 19 are removed in the NMOS area. Subsequently, a process of siliciding the polysilicon electrode 18A is performed. Going into details, as shown in FIG. 8B, the whole surface of the silicon substrate 10 is covered with the organic anti-reflective film 16, and further, the photoresist layer 17 is formed by the photolithography technique. The photoresist layer 17 is formed to cover the PMOS area. Typically, the organic anti-reflective film 16 is formed by using spin coating. The concentration of a solution used for spin coating is so selected that the stopper nitride film 21 may not be exposed, and the whole surface of the silicon substrate 10 may be covered with the organic anti-reflective film 16.

Subsequently, as shown in FIG. 8C, the organic anti-reflective film 16 is etched by using the photoresist layer 17 as a mask. This etching is performed until a part of the stopper nitride film 21 is exposed in the NMOS area, which makes the organic anti-reflective film 16 remain on the gate insulating film 11. The etching of the organic anti-reflective film 16 is performed under the condition that the etching rate of the organic material of the organic anti-reflective film 16 becomes higher than that of the silicon nitride film. Preferably, a mixed gas of O₂ and Cl₂ is used as an etching gas for etching the organic anti-reflective film 16.

Subsequently, as shown in FIG. 8D, only in the NMOS area, a part of the stopper nitride film 21 that covers the polysilicon electrode 18B is removed by etching, and further the polysilicon electrode 18B is etched. In the PMOS area, the stopper nitride film 21 and the polysilicon electrode 18B are not etched. The etching is performed until the polysilicon electrode 18B in the NMOS area is removed completely. The etching of the stopper nitride film 21 is performed under the condition that the etching rate of the silicon nitride film becomes higher than that of the organic material of the organic anti-reflective film 16 and that of the polysilicon electrode 18B. On the other hand, the etching of the polysilicon electrode 18B is performed under the condition that the etching rate of polysilicon becomes considerably higher than that of the organic material of the organic anti-reflective film 16 and that of the silicon nitride film.

Preferably, fluorocarbon including a hydrogen atom(s), such as CHF₃, CH₂F₂, and CH₃F is used as an etching gas material in etching the stopper nitride film 21, like the case in the second embodiment. By using the fluorocarbon as the etching gas, the stopper nitride film 21 formed on the polysilicon electrode 18B can be removed while leaving the polysilicon electrode 18B and the organic anti-reflective film 16.

On the other hand, preferably, a gas containing HBr is used for an etching gas in etching the polysilicon electrode 18B. HBr functions as an etchant for etching polysilicon, and the use of pure HBr as the etching gas can increase the etching selectivity of the gate electrode 15 to the photoresist layer 17 to be more than or equal to 10.

Subsequently, as shown in FIG. 8E, the protection nitride film 19 located in the NMOS area is removed by etching, and further the organic anti-reflective film 16 and the photoresist layer 17 are removed. Preferably, fluorocarbon containing a hydrogen atom(s), such as CHF₃, CH₂F₂, and CH₃F is used as an etching gas material in etching the protection nitride film 19, like the stopper nitride film 21. Removal of the organic anti-reflective film 16 and the photoresist layer 17 is performed by ashing, SPM washing, ozonization, or combinations thereof. The organic anti-reflective film 16 and the photoresist layer 17 are easily removable, and therefore according to the process as described above, it is possible to lessen the etching residue. After the removal of the organic anti-reflective film 16 and the photoresist layer 17, only the polysilicon electrode 18A located in the NMOS area is exposed. The polysilicon electrode 18A located in the PMOS area is covered with the protection nitride film 19, the polysilicon electrode 18B, and the stopper nitride film 21.

By adding O₂ gas to the etching gas of the stopper nitride film 21, the polysilicon electrode 18B, and the protection nitride film 19, the etching selectivity can be adjusted. However, from a viewpoint of protecting the silicon substrate 10 by leaving the organic anti-reflective film 16, it is undesirable that the ratio of O₂ gas included in the etching gas of the stopper nitride film 21 and the polysilicon electrode 18B is excessively high. The ratio of O₂ gas in the etching gas of the stopper nitride film 21, the polysilicon electrode 18B, and the protection nitride film 19 is controlled low compared with the ratio of O₂ gas in the etching gas of the organic anti-reflective film 16.

Subsequently, as shown in FIG. 8F, the polysilicon electrode 18A in the NMOS area is silicided to form the silicide gate electrode 22. Typically, the silicidization of the polysilicon electrode 18A is performed by depositing a nickel film and successive annealing. By the above procedures, the process of selectively siliciding the polysilicon electrode 18A in the NMOS area is completed.

Subsequently, as shown in FIG. 8G, the whole surface of the silicon substrate 10 is covered with the stopper nitride film 23. It is preferable that the stopper nitride film 23 is formed to have a large thickness only above the polysilicon electrode 18 in the NMOS area. In order to form the stopper nitride film 23 like this, it is preferable to form the silicon nitride film having a large thickness, and subsequently etch back a part thereof other than a part above the polysilicon electrode 18 in the NMOS area.

Subsequently, a process of siliciding the polysilicon electrode 18A in the PMOS area is performed. Specifically, first, as shown in FIG. 8H, the whole surface of the silicon substrate 10 is covered with the organic anti-reflective film 24, and further the photoresist layer 25 is formed by the photolithography technique. The photoresist layer 25 is formed to cover the NMOS area. Typically, the organic anti-reflective film 24 is formed by using spin coating. The concentration of a solution used for spin coating is selected so that the upper part of the stopper nitride film 23 may not be exposed and the whole surface of the silicon substrate 10 may be covered with the organic anti-reflective film 16.

Subsequently, as shown in FIG. 8I, the organic anti-reflective film 24 is etched by using the photoresist layer 25 as a mask. This etching is performed until a part of the stopper nitride film 23 is exposed in the PMOS area, and the organic anti-reflective film 24 is left. The etching of the organic anti-reflective film 24 is performed under the condition that the etching rate of the organic material of the organic anti-reflective film 24 becomes higher than that of the silicon nitride film. Preferably, a mixed gas of O₂ and Cl₂ is used as the etching gas for etching the organic anti-reflective film 24.

Subsequently, as shown in FIG. 8J, only for the PMOS area, parts of the stopper nitride films 21 and 23 that cover the polysilicon electrodes 18B is removed by etching, and further the polysilicon electrode 18B is etched. The stopper nitride films 21 and 23 are not etched in the NMOS area. The etching is performed until the polysilicon electrode 18B in the PMOS area is removed completely. The etching of the stopper nitride films 21 and 23 is performed under the condition that the etching rate of the silicon nitride film becomes considerably higher than that of the organic material of the organic anti-reflective film 24 and that of the polysilicon electrode 18B. On the other hand, the etching of the polysilicon electrode 18B is performed under the condition that the etching rate of polysilicon becomes considerably higher than that of the organic material of the organic anti-reflective film 24 and that of the silicon nitride film.

Subsequently, as shown in FIG. 8K, the protection nitride film 19 located in the PMOS area is removed by etching, and further the organic anti-reflective film 24 and the photoresist layer 25 are removed. Like the etching of the stopper nitride film 21, preferably, the fluorocarbon including a hydrogen atom (s), such as CHF₃, CH₂F₂, and CH₃F are used for a gas in etching the protection nitride film 19. The removal of the organic anti-reflective film 24 and the photoresist layer 25 is performed by ashing, SPM washing, ozonization, or combinations of them. The organic anti-reflective film 24 and the photoresist layer 25 are easily removable, and therefore according to a process as described above, the etching residue can be lessened. After the removal of the organic anti-reflective film 24 and the photoresist layer 25, only the polysilicon electrode 18A located in the PMOS area is exposed. The silicide gate electrode 22 located in the NMOS area is covered with the stopper nitride film 23.

Subsequently, as shown in FIG. 8L, the polysilicon electrode 18A in the PMOS area is silicided to form the silicide gate electrode 22. Typically, silicidization of the polysilicon electrode 18A is performed by depositing a nickel film and successive annealing. Through the above procedures, a process of selectively siliciding the polysilicon electrode 18A in the PMOS area is completed.

Subsequently, the stopper nitride film for covering the silicide gate electrode 22 in the PMOS area is formed, and the process of siliciding the polysilicon electrode 18A is completed.

As described above, in the manufacturing method of the semiconductor device of the present embodiment, after the organic anti-reflective film 16 covers the whole surface of the silicon substrate 10, the organic anti-reflective film 16 is partially etched and a part of the stopper nitride film 21 to be etched is selectively exposed. According to a process like this, even if there are varieties of the packing density and the size of the polysilicon electrodes 18A and 18B, it is possible to selectively etch a target part of the stopper silicide film 21 and the polysilicon electrode 18B and the protection nitride film 19 that are located under it while protecting the silicon substrate 10. In addition, since the organic anti-reflective film 16 covers the whole surface of the silicon substrate 10, it does not cause the problem of reflection in a photolithography process of patterning the photoresist layer 17, so that the photoresist layer 17 can be formed in a desired shape.

It should be noted that although the embodiments of the manufacturing method of the semiconductor device according to the present invention have been described in detail, the present invention is not restricted to the above-mentioned embodiments. For example, in the present invention, it is also possible to put structures formed of materials other than polysilicon and silicon nitride, such as silicon oxide (SiO₂), silicon oxide nitride (SiON), and silicon oxide carbide (SiOC). In this case, it is obvious to the person skilled in the art that the etching gas is suitably changed according to a structure of the processing target.

Moreover, although the organic anti-reflective film is used for protecting the semiconductor substrate in the above-mentioned embodiment, it is also possible to use a material other than the organic anti-reflective film. If a coating film is made of a material that can exhibit the very high etching selectivity against structures of Si, SiO₂, SiN, etc. using a specific gas (for example, oxygen) as an etching gas, it is possible to use that coating film for protection of the semiconductor substrate.

Although the present invention has been described above in connection with several embodiments thereof, it would be appreciated by those skilled in the art that those embodiments are provided solely for illustrating the present invention, and should not be relied upon to construe the appended claims in a limiting sense.

What is claimed is:

1. A method of manufacturing a semiconductor device, comprising:
forming a plurality of structures on a substrate;
forming a coating film over a whole surface of the substrate to cover said plurality of structures;
forming a photoresist layer to have an opening portion above a target structure of said plurality of structures;
etching the coating film on a side of the opening to expose a part of the target structure by using the photoresist layer as a mask while maintaining the substrate in a state covered with the coating film;
etching a target portion as at least a portion of the target structure while leaving the coating film; and
removing the photoresist layer and the coating film.

2. The method according to claim 1, wherein the coating film is made mainly of carbon.

3. The method according to claim 2, wherein said etching the coating film is performed under a condition that an etching rate of the coating film made mainly of carbon is higher than that of the target portion, and
said etching the target structure is performed under a condition that the etching rate of the target portion is higher than that of the coating film made mainly of carbon.

4. The method according to claim 2, wherein the coating film made mainly of carbon is an organic anti-reflective film.

5. The method according to any of claim 2, wherein said removing comprises:
removing the photoresist layer and the coating film by ashing, SPM washing, ozonization, or combinations thereof.

6. The method according to claim 2, wherein the coating film made mainly of carbon is formed using spin coating.

7. The method according to claim 2, wherein the plurality of structures contains a plurality of gate electrodes formed of polysilicon, and
the target structure is a part of the plurality of gate electrodes.

8. The method according to claim 2, wherein the target structure includes a polysilicon electrode, and a protection nitride film formed to cover the polysilicon electrode, and
said etching a target portion comprises:
etching the protection nitride film as the target portion.

9. The method according to claim 8, wherein the target structure includes a polysilicon electrode, a protection nitride film formed to cover the polysilicon electrode, sidewalls formed to cover sides of the polysilicon electrode and the protection nitride film, and a stopper nitride film formed of silicon nitride to cover the protection nitride film and the sidewalls, and
said etching a target portion comprises:
etching a part of the stopper nitride film and the protection nitride film as the target portion.

10. The method according to claim 9, further comprising:
siliciding the polysilicon electrode.
